(19) United States
(12) Patent Application Publication
(10) Pub. No.: US 2008/0018238 A1
(43) Pub. Date: Jan. 24, 2008

(54) Use Of Phenothiazine-S-Oxides And Phenothiazine -S,S-Dioxides In The Form Of Matrix Materials For Organic Light-Emitting Diodes

(75) Inventors: Thomas Gessner, Heidelberg (DE); Wolfgang Kowalsky, Braunschweig (DE); Christian Schildknecht, Braunschweig (DE)

Correspondence Address: OBLON, SPIVAK, MCCLELLAND MAIER & NEUSTADT, P.C., 1940 DUKE STREET, ALEXANDRIA, VA, 22314, US

(73) Assignee: BASF Aktiengesellschaft, Ludwigshafen (DE)

(21) Appl. No.: 11/720,156

(22) PCT Filed: Nov. 23, 2005
(86) PCT No.: PCT/EP05/12527

§ 371 Date: May 24, 2007

(30) Foreign Application Priority Data
Nov. 25, 2004 (DE) 10 2004 057 073.6

(51) Int. Cl. H01L 51/50; C09K 11/06

(52) U.S. Cl. 313/504; 252/301.16

(57) ABSTRACT

The present invention relates to the use of phenothiazine S-oxides and S,S-dioxides as matrix materials for organic light-emitting diodes, in particular as matrix materials in the light-emitting layer of the organic light-emitting diodes, to organic light-emitting diodes comprising a light-emitting layer which comprises at least one phenothiazine S-oxide or S,S-dioxide as a matrix material and at least one further substance distributed therein as an emitter, to light-emitting layers which comprise at least one phenothiazine S-oxide or S,S-dioxide as a matrix material and at least one substance distributed therein as an emitter, to light-emitting layers which consist of one or more phenothiazine S-oxides or S,S-dioxides as a matrix material and at least one further substance distributed therein as a matrix material, to organic light-emitting diodes which comprise corresponding light-emitting layers, and to devices which comprise corresponding organic light-emitting diodes.

The present invention relates to the use of phenothiazine S-oxides and S,S-dioxides as matrix materials for organic light-emitting diodes, in particular as matrix materials in the light-emitting layer of the organic light-emitting diodes, to organic light-emitting diodes comprising a light-emitting layer which comprises at least one phenothiazine S-oxide or S,S-dioxide as a matrix material and at least one further substance distributed therein as an emitter, to light-emitting layers which comprise at least one phenothiazine S-oxide or S,S-dioxide as a matrix material and at least one further substance distributed therein as an emiffer, to light-emitting layers which consist of one or more phenothiazine S-oxides or S,S-dioxides as a matrix material and at least one further substance distributed therein as a matrix material, to organic light-emitting diodes which comprise corresponding light-emitting layers, and to devices which comprise corresponding organic light-emitting diodes.

In organic light-emitting diodes (OLEDs), the property of materials of emitting light when they are excited by electrical current is exploited, OLEDs are especially interesting as an alternative to cathode ray tubes and liquid crystal displays for the production of flat visual display units. Owing to the very compact design and the intrinsically low power consumption, devices comprising OLEDs are suitable especially for mobile applications, for example for applications in mobile telephones, laptops, etc.

Numerous materials have been proposed which emit light on excitation by electrical current. These materials may function as light emitters per se or they consist of a matrix material which comprises the actual light emitter in distributed form.

According to the prior art, phenoxazine and phenothiazine derivatives are generally used as charge transport materials.

For instance, EP-A 0 517 542 relates to aromatic amino compounds which feature good thermal stability and can have, inter alia, a phenothiazine unit. These aromatic amino compounds are used as hole transport materials in OLEDS.

EP-A 0 562 883 likewise relates to hole transport materials which are used in OLEDs and which have a high thermal stability. The hole transport materials used are tris(phenothiazinyl)triphenylamine derivatives or tris(phenoxazinyl)triphenylamine derivatives.

DE-A 101 43 249 relates to a process for preparing conjugated oligo- and polyphenothiazines and to their use as hole conductors in organic light-emitting diodes and field-effect transistors. The oligo- and polyphenothiazines are prepared by means of cross-coupling of functionalized phenothiazine derivatives.

EP-A 0 535 672 discloses an electrophotographic photoreceptor which comprises an organic conductive material in its photosensitive layer. Suitable organic conductive materials include compounds which have phenothiazine structural units.

U.S. Pat. No. 5,942,615 and JP-A 11-158165 relate to phenothiazine and phenoxazine derivatives, to a charge transport material which comprises these derivatives, and to an electrophotographic photoreceptor which comprises the disclosed charge transport material. The phenothiazine or phenoxazine derivatives are derivatives of the following formula: 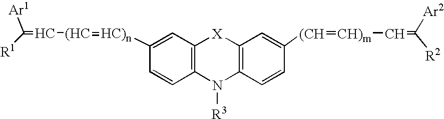
where Ar¹ and Ar² are each aryl groups, R¹ and R² are each H, lower alkyl or aryl, R³ is lower alkyl an alicyclic hydrocarbon radical having from 5 to 7 carbon atoms, aryl or arylalkyl, X is S or O, and m and n are each 0 or 1. With regard to luminescence, especially electroluminescence, of the aforementioned compounds, neither U.S. Pat. No. 5,942,615 or JP-A 11-158165 contain any information.

In addition, the prior art discloses some ver specific phenothiazine and phenoxazine derivatives which are used as luminescent materials in the light-emitting layer of an OLED.

For instance, JP-A 2003-007466 relates to an OLED which has a long lifetime and high illumination density and comprises, as the luminescent material, a polymer which has repeat units based on phenothiazine or phenoxazine derivatives.

JP-07-109449 describes, inter alia, the phenothiazine S,S-dioxide derivative 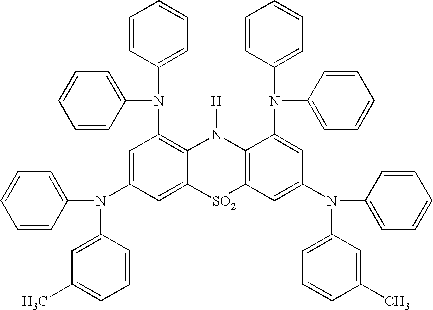
as a material in OLEDs.

JP-A 2000-328052 relates to a luminescent material which emits light in the yellow to red region of the electromagnetic spectrum and is composed of a monocyclic or fused polycyclic compound which has two specific substituents. These specific substituents are substituents of the following formula:

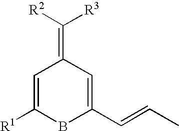

In this formula,
B is S or O,
R¹ is H, alkyl or aryl and
R², R³ are each independently selected from H, CN, halogen, alkylcarbonyl and alkoxycarbonyl; R² and R³ are preferably each CN.

Phenothiazine and phenoxazine derivatives are mentioned as fused polycyclic compounds.

KR 2003-0029394 relates to red luminophores which are suitable for organic electroluminescence. These luminophores have a phenocyanidine group which has good hole transport properties and an anthracenyl radical which has a good electron transport capacity. Depending on the substitution pattern of the luminophores, they do not only exhibit luminescence in the yellow and red, but also in the green region of the electromagnetic spectrum. These specific luminophores have one of the following formulae

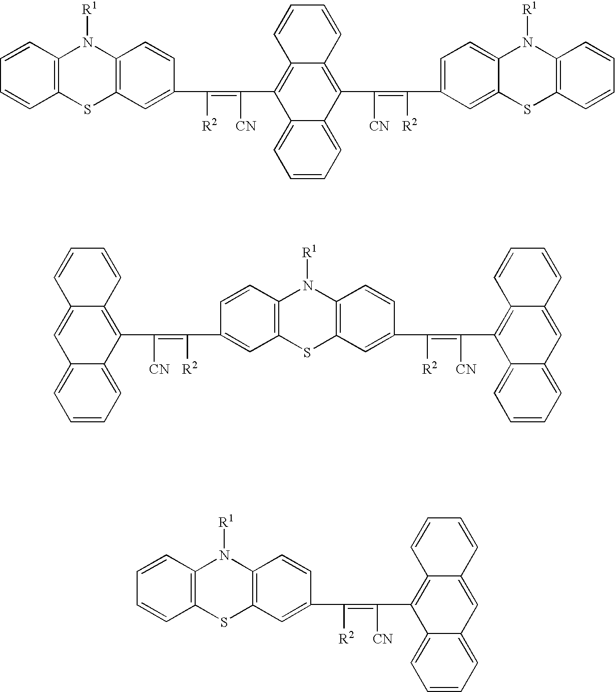

The R¹ and R² radicals may be H, aryl, heteroaryl, halogen or saturated or unsaturated hydrocarbons. A special feature of these compounds which is emphasized is that they do not only have light emission properties, but also hole transport properties and electron transport properties, owing to their particular substitution pattern.

JP-A 2004-075750 relates to phenoxazine derivatives of the formula 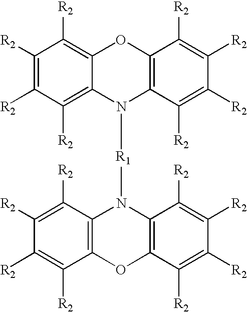
where R₁ is an aromatic or aliphatic connecting group and R₂ is an alkyl, alkenyl, alkyl ether, alkoxy, amino, aryl or aryloxy group. The phenoxazine derivatives are used as fluorescent substances in the light-emitting layer of an OLED.

It is an object of the present application to provide matrix materials for use in OLEDs, especially in the light-emitting layers of the OLEDs, which are readily obtainable and, in combination with the actual emitter(s), bring about good illumination densities and quantum yields in OLEDs.

This object is achieved by the use of compounds of the formula I 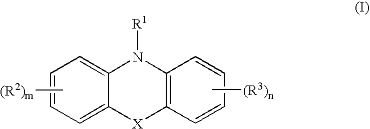
where:
X is an SO or SO₂ group,
R¹ is hydrogen, alkyl, cyclic alkyl, heterocyclic alkyl, aryl heteroaryl,
a moiety of the formula II 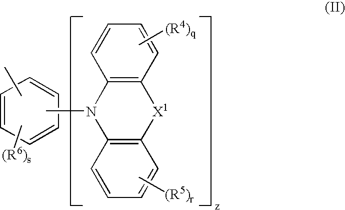
a moiety of the formula III 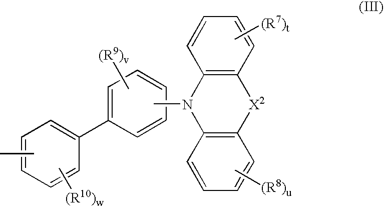
or
a moiety of formula IV 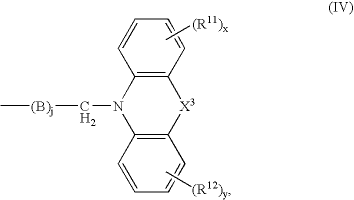
X¹, X², X³ are each independently, and independently of X, and SO or SO₂ group,
R², R³, R⁴, R⁵, R⁷, R⁸, R¹¹, R¹² are each independently alkyl, aryl or heteroaryl,
m, n, q, r, t, u, x, y are each independently 0, 1, 2, or 3,
R⁶, R⁹, R¹⁰ are each independently alkyl, aryl, alkoxy or aryloxy
S, v, w are each independently 0, 1 or 2,
B is an alkylene bridge —CH₂—CₖH₂ₖ— in which one or more nonadjacent CH₂ groups of the —CₖH₂ₖ— unit may be replaced by oxygen or NR,
R is hydrogen or alkyl,
k is 0, 1, 2, 3, 4, 5, 6, 7 or 8,
j is 0 or 1
   and
z is 1 or 2,
   as matrix materials in organic light-emitting diodes.

The matrix materials of the formula I which are used in accordance with the invention are readily obtainable and have, in combination with the actual emitter(s), good illumination densities and quantum yields when used in OLEDs.

The alkyl radicals, and the alkyl radicals of the alkoxy groups, in the present application may be either straight-chain or branched and/or optionally substituted by substituents selected from the group consisting of aryl, alkoxy and halogen. The alkyl radicals are preferably unsubstituted. Suitable aryl substituents are specified below.

The cyclic alkyl radicals, and the cyclic alkyl radicals of the alkoxy groups, in the present application may optionally be substituted by substituents selected from the group consisting of aryl, alkoxy and halogen. The cyclic alkyl radicals are preferably unsubstituted. Suitable aryl substituents are specified below.

Suitable halogen substituents are fluorine, chlorine, bromine and iodine, preferably fluorine, chlorine and bromine, more preferably fluorine and chlorine.

Examples of suitable alkyl groups are methyl, ethyl, propyl, butyl, pentyl, hexyl, heptyl and octyl. This includes both the n-isomers of these radicals and branched isomers such as isopropyl, isobutyl, isopentyl, sec-butyl, tert-butyl, neopentyl, 3,3-dimethylbutyl, 2-ethylhexyl, etc. Preferred alkyl groups are methyl and ethyl.

Examples of suitable cyclic alkyl radicals are cyclopropyl, cyclobutyl, cyclopentyl, cyclohexyl, cycloheptyl, cyclooctyl, cyclonoryl and cyciodecyl. They may also be polycyclic ring systems such as decalinyl, norbornanyl, bornanyl or adamantyl. The cyclic alkyl radicals may be unsubstituted or optionally substituted by one or more further radicals, as listed by way of example above for the alkyl radicals.

Suitable alkoxy groups derive correspondingly from the alkyl radicals as defined above. Examples include OCH₃, OC₂H₅, OC₃H₇, OC₄H₉ and OC₈H₁₇. C₃H₇, C₄H₉ and OC₈H₁₇ include both the n-isomers and branched isomers such as isopropyl, isobutyl, sec-butyl, tert-butyl and 2-ethylhexyl. Particular preference is given to methoxy, ethoxy, n-octoxy and 2-ethylhexoxy.

In the present invention, aryl refers to radicals which are derived from monocyclic or bicyclic aromatics which do not contain any ring heteroatoms. When they are not monocyclic systems, the saturated form (perhydro form) or the partly unsaturated form (for example the dihydro form or tetrahydro form) are also possible for the second ring in the term aryl, as long as the particular forms are known and stable. This means that the term aryl in the present invention also includes, for example, bicyclic radicals in which both the radicals are aromatic and bicyclic radicals in which only one ring is aromatic. Examples of aryl are: phenyl, naphthyl, indanyl, 1,2-dihydronaphthenyl, 1,4-dihydronaphthenyl, indenyl or 1,2,3,4-tetrahydronaphthyl. Aryl is more preferably phenyl or naphthy, most preferably phenyl.

The aryl radicals may be unsubstituted or substituted by one or more further radicals. Suitable further radicals are selected from the group consisting of alkyl, aryl, alkoxy, aryloxy, arylcarbonyloxy, heteroaryl, hydroxyl and halogen. Preferred alkyl, aryl, alkoxy and halogen radicals have already been specified above. The aryl radicals are preferably unsubstituted or substituted by one or more alkoxy groups. Aryl is more preferably unsubstituted phenyl, 4-alkylphenyl, 4-alkoxyphenyl, 2,4,6-trialkylphenyl or 2,4,6-trialkoxyphenyl, and 4-alkylphenyl, 4-alkoxyphenyl, 2,4,6-trialkylphenyl and 2,4,6-trialkoxyphenyl are in particular 4-methylphenyl, 4-methoxyphenyl, 2,4,6-trimethylphenyl and 2,4,6-trimethoxyphenyl.

Suitable aryloxy groups and arylcarbonyloxy groups derive correspondingly from the aryl radicals as defined above, Particular preference is given to phenoxy and phenylcarbonyloxy.

Heteroaryl refers to monocyclic or bicyclic heteroaromatics, some of which can be derived from the above-specified aryl in that at least one carbon atom in the basic aryl structure has been replaced by a heteroatom. Preferred heteroatoms are X, O and S. Especially preferably, the basic structure which is optionally fused is selected from systems such as pyridine and five-membered heteroaromatics such as thiophene, pyrrole, imidazole or furan. The basic structure may be substituted at one substitutable position or at a plurality of or all substitutable positions, in which case suitable substituents are the same as have already been specified under the definition of aryl. However, the heteroaryl radicals are preferably unsubstituted. Mention should be made here in particular of pyridin-2-yl, pyridin-3-yl, pyridin-4-yl, thiophen-2-yl, thiophen-3-yl, pyrrol-2-yl, pyrrol-3-yl, furan-2-yl, furan-3-yl and imidazol-2-yl, and the corresponding benzofused radicals.

Heterocyclic alkyl refers to radicals which differ from the above-specified cyclic alkyl in that at least one carbon atom in the basic cyclic alkyl structure has been replaced by a heteroatom. Preferred heteroatoms are N, O and S. The basic structure may be substituted at one substitutable position or at a plurality of or all substitutable positions, in which case suitable substituents are the same as have already been specified under the definition of aryl. Mention should be made here in particular of the nitrogen-containing radicals pyrrolidin-2-yl, pyrrolidin-3-yl, piperidin-2-yl, piperidin-3-yl, piperidin-4-yl.

The —CₖH₂ₖ— unit of the alkylene bridge B refers in particular to the linear alkylene chains —CH₂—, —(CH₂)₂—, —(CH₂)₃—, —(CH₂)₄—, —(CH₂)₅—, —(CH₂)₆—, —(CH₂)₇— and —(CH₂)₈—. However, they may also be branched, so that, for example, —CH(CH₃)—, —C(CH₃)₂—, —CH₂—CH(CH₃)—, —CH(CH₃)—CH(CH₃)—, —C(CH₃)₂—C(CH₃)₂—, —CH(CH₃)—CH₂—CH(CH₃)—, —CH(CH₃)—(CH₂)₂—CH(CH₃)—, —CH(H₃)—(CH₂)₃—CH(CH₃)—, —CH(CH₃)—(CH₂)₄—CH(CH₃)—, —C(CH₃)₂—CH₂—C(CH₃)₂— or —C(CH₃)₂—(CH₂)₂—C(CH₃)₂— chains are also possible. In addition, one or more nonadjacent CH₂— groups in the —CₖH₂ₖ— unit of the alkylene bridge B may be replaced by oxygen or NR. Examples thereof are in particular —O—C₂H₄—O—, —(C₂H₄—O—)₂, —NR—C₂H₄—NR— or —NR—(2H₄—NR—)₂, where R is in particular hydrogen, ethyl, ethyl, propyl, isopropyl, butyl, sec-butyl or tert-butyl.

When R¹ assumes the definition of a moiety of the formula II where z equals 2, the two (4)_{q} and (R⁵)ᵣ may differ from one another in type and number. In addition, the two X¹ may also differ from one another.

The optionally substituted phenothiazine skeletons of the formulae I and II are preferably the same, i.e. (R²)ₘ and (R⁵)ᵣ, (R³)ₙ and (R⁴)_{q}, and X and X¹ (where z=1), or (R²)ₘ and the two (R⁵)ᵣ, (R³)ₙ and the two (R⁴)_{q}, and X and the two X¹ (where z=2) each have the same definition.

When R¹ assumes the definition of the formula III, the optionally substituted phenothiazine skeletons of the formulae I and III are preferably the same, i.e. (R²)ₘ and (R⁸)ᵤ, (R³)ₙ and (R⁷)ₜ, and X and X² each have the same definition.

When R¹ assumes the definition of a moiety of the formula IV, the optionally substituted phenothiazine skeletons of the formulae I and IV are preferably the same, i.e. (R²)ₘ and (R¹¹)ₓ, (R³)ₙ and (R¹²)_{y}, and X and X³ each have the same definition.

In a preferred embodiment, the present invention relates to the use of compounds of the formula I in which the variables are each defined as follows:
X is an SO or SO₂ group,
R¹ is hydrogen, methyl, ethyl, cyclohexyl, pyrrolidin-2-yl, pyrrolidin-3-yl, piperidin-2-yl, piperidin-3-yl, piperidin-4-yl, phenyl, 4-alkylphenyl, 4-alkoxyphenyl, 2,4,6-trialkylphenyl, 2,4,6-trialkoxyphenyl, furan-2-yl, furan-3-yl, pyrrol-2-yl, pyrrol-3-yl, thiophen-2-yl, thiophen-3-yl, pyridin-2-yl, pyridin-3-yl, pyridin-4-yl, pyrimidin-2-yl, pyrimidin-4-yl, pyrimidin-5-yl, sym-triazinyl, phenyl, 4-alkoxyphenyl,
   a moiety of the formula II 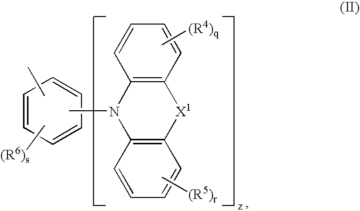
   a moiety of the formula III 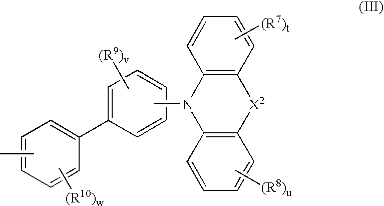
   or
   a moiety of the formula IV 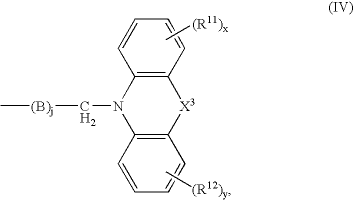
X¹, X², X³ are each independently, and independently of X, an SO or SO₂ group,
R², R³, R⁴, R⁵, R⁷, R⁸, R¹¹, R¹² are each independently aryl,
m, n, q, r, t, u, x, y are each independently 0 or 1,
R⁶, R⁹, R¹⁰ are each independently alkyl or alkoxy,
s, v, w are each independently 0 or 1,
B is an alkylene bridge —CH₂—CₖH₂ₖ—,
k is Q, 1, 2, 3, 4, 5, 6, 7 or S,
j is 0 or 1
   and
z is 1 or 2.

Aryl in the R², R³, R⁴, R⁵, R⁷, R⁸, R¹¹ and R¹² radicals is preferably each independently phenyl, naphth-1-yl or naphth-2-yl.

When R¹ assumes the definition of a moiety of the formula II where z equals 2, the two (R⁴)_{q} and (R⁵)ᵣ may differ in type and number. In addition, the two X¹ may also differ from one another.

The optionally substituted phenothiazine skeleton of the formulae I and II are preferably the same, i.e. (R²)ₘ and (R⁵)ᵣ, (R³)ₙ, and (R⁴)_{q}, and X and X¹ (where z=1), or (R²)ₘ and the two (R⁵)ᵣ, (R³)ₙ and the X¹ (where z=2) each have the same definition.

When R¹ assumes the definition of a moiety of the formula III, the optionally substituted phenothiazine skeletons of the formulae I and III are preferably the same, i.e. (R²)ₘ and (R⁸)ᵤ, (R³)ₙ and (R⁷)ₜ, and X and X² each have the same definition.

When R¹ assumes the definition of a moiety of the formula IV, the optionally substituted phenothiazine skeletons of the formulae I and IV are preferably the same, i.e. (R²)ₘ and (R¹¹)ₓ, (R³)ₙ and (R¹²)_{y}, and X and X³ each have the same definition.

Examples of compounds of the formula I in which R¹ is defined as hydrogen, alkyl, cyclic alkyl, heterocyclic alkyl, aryl or heteroaryl are listed below. 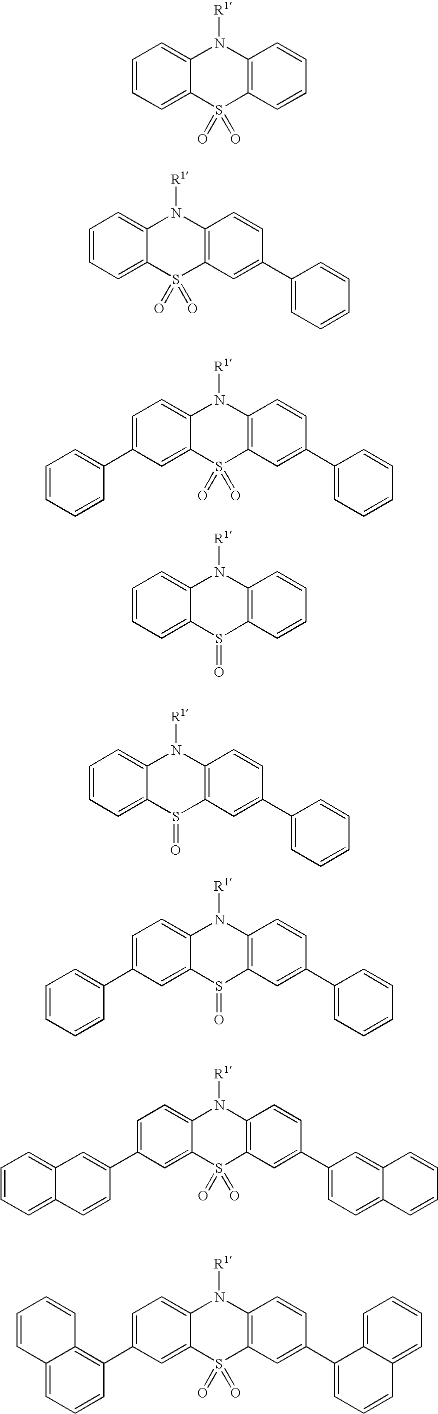 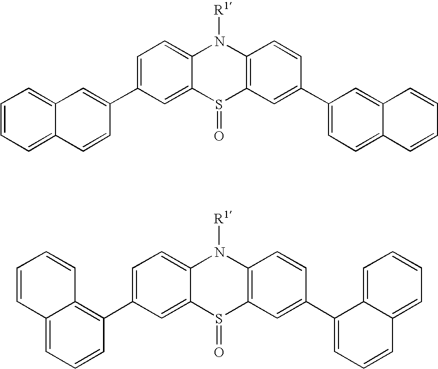
where R^{1′} is one of the following groups

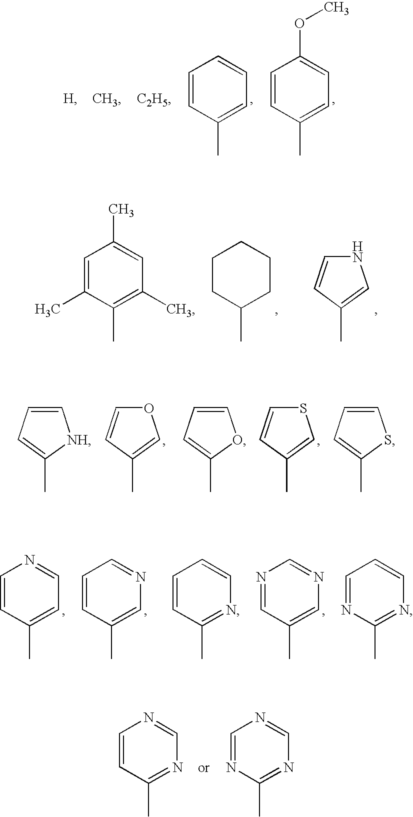

Examples or compounds of the formula I in which R¹ is defined as a moiety of the formula II are listed below:
where z=1 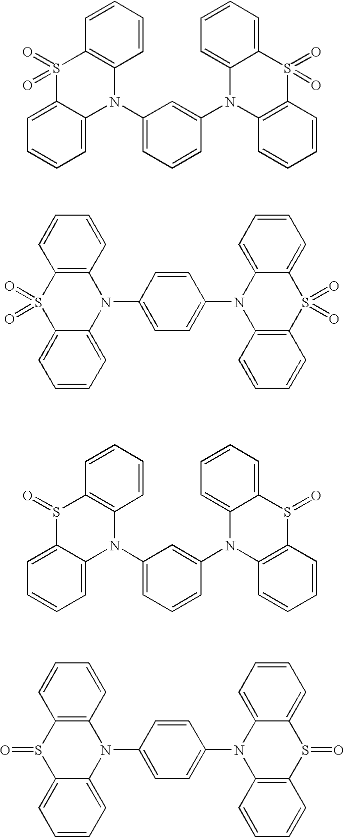
where z=2

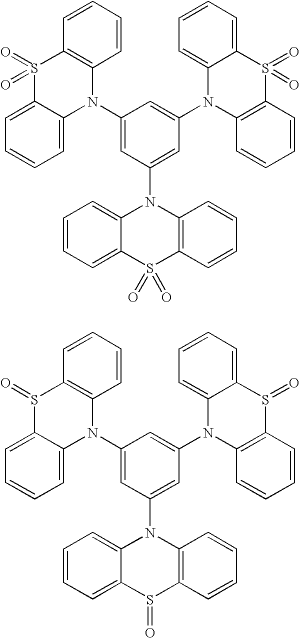

Examples of compounds of the formula I in which R¹ is defined as a moiety of the formula III are listed below:

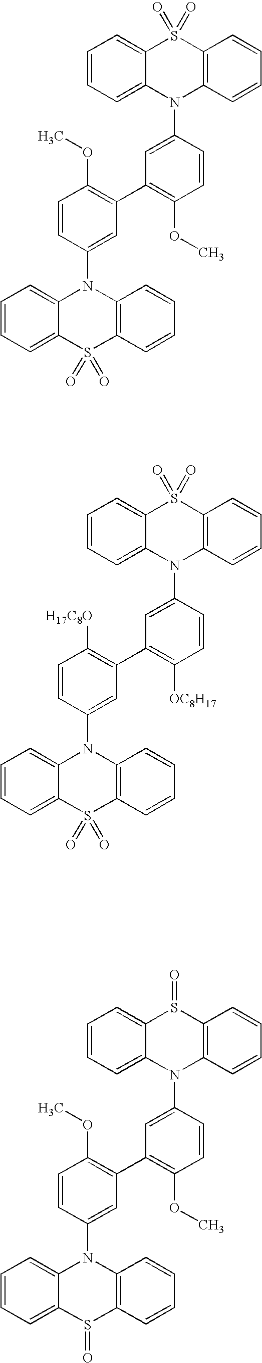

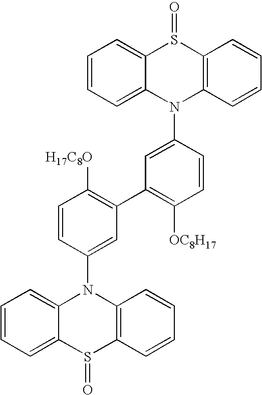

Examples of compounds of the formula I in which R¹ is defined as a moiety of the formula IV are listed below: 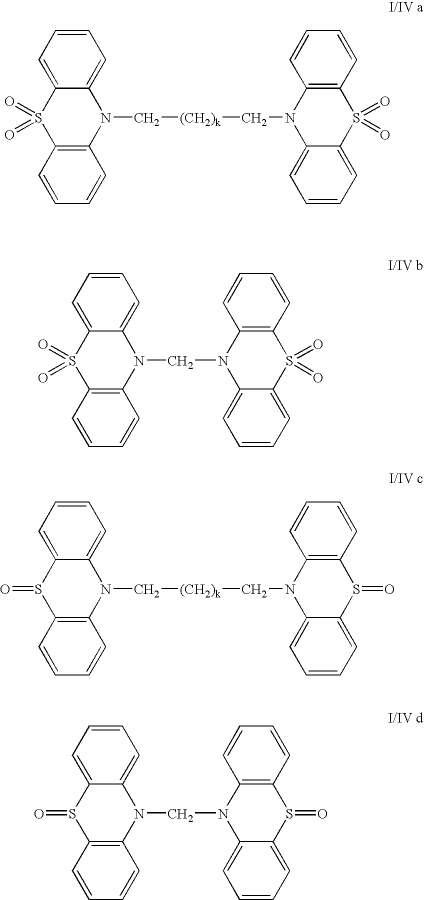
where k in the formulae I/IV a and I/IV c can in each case assume the values 0 or from 1 to 8 and, for the formulae I/IV b and I/IV d, the value of j in the —(B)—H₂— bridging unit is in each case 0.

The listed phenothiazine S-oxide or phenothiazine S,S-dioxide derivatives of the formula I used in accordance with the invention may be prepared by processes known to those skilled in the art.

The compounds of the formula I are prepared preferably by appropriately substituting the commercially available basic phenothiazine skeleton (i.e. m and n are both equal to 0). The R² and/or R³ radicals are introduced by electrophilic aromatic substitution. Suitable reaction conditions are known to those skilled in the art. When it is not hydrogen, the R¹ radical is introduced by electrophilic substitution on the nitrogen, for example by reacting with a suitable alkyl halide or aryl halide. The sulfur in the phenothiazine skeleton is oxidized to the SO or SO₂ group typically in the last synthetic step.

However, the compounds of the formula I may also alternatively be prepared starting from already functionalized building blocks suitable for preparing the phenothiazine S-oxide or phenothiazine S,S-dioxide derivatives. For example, the phenothiazine derivatives used in accordance with the invention may be prepared starting from diphenylamine derivatives functionalized with the R² and/or R³ radicals by heating with sulfur. The preparation of the functionalized diphenylamine derivatives is known to those skilled in the art. Here too, the sulfur in the phenothiazine skeleton is then oxidized to the SO or SO₂ group typically in the last synthetic step.

Suitable processes for oxidizing the phenothiazines to the phenothiazine S-oxides and phenothiazine S,S-dioxides used in accordance with the invention are known to those skilled in the art and are specified, for example, in M. Tosa et al. Heterocyclic Communications, Vol. 7 No. 3, 2001, p. 277 to 282.

The oxidation to phenothiazine S-oxide derivatives is effected, for example, by means of H₂O₂ in ethanol ethanol-acetone mixtures or oxalic acid, by means of ammonium persulfate, nitric acid, nitrous acid, inorganic nitrogen oxides, if appropriate together with (atmospheric) oxygen, NO⁺BF₄⁻/O₂, CrO₃ in pyridine, ozone, tetramethyloxirane, perfluoroalkyloxaziridines or by means of electrochemical methods. In addition, the appropriately functionalized phenothiazines of the formula I can be oxidized to the corresponding phenoxazine S-oxide derivatives of the formula I by means of m-chloroperbenzoic acid in CH₂Cl₂ at temperatures of from 0 to 5° C. or by means of a mixture of fuming nitric acid and glacial acetic acid in CCl₄ (see, for instance, M. Tosa et al. Heterocyclic Communications, Vol. 7, No. 3, 2001, p. 277 to 282).

The oxidation to phenothiazine S,S-dioxide derivatives is effected, for example, by means of peracids such as peracetic acid which is obtainable, for example, from H₂O₂ and AcOH, or m-chloroperbenzoic acid, sodium perborate, NaOCl, or heavy metal systems such as KMnO₄/H₂O, Et₃PhN⁺MnO₄⁻ in organic media, OsO₄/N-methylmorpholine N-oxide. For instance, the appropriately functionalized phenothiazines of the formula I can be oxidized to the corresponding phenothiazine S,S-dioxide derivatives of the formula I by means of an aqueous solution of KMnO₄ and C₁₆H₃₅N(CH₃)₃⁺Cl⁻ in CHCl₃ at room temperature, or by means of m-chloroperbenzoic acid in CH₂Cl₂ at room temperature (see, for instance, M. Tosa et al. Heterocyclic Communications, Vol. 7, No. 3, 2001, p, 277-282).

To prepare the phenothiazine S,S-dioxide derivatives, the phenothiazine derivative and the oxidizing agent, preferably m-chloroperbenzoic acid, are used in a molar ratio of generally from 1:1.8 to 1:4, preferably from 1:1.9 to 1:3.5, more preferably from 1:1.9 to 1:3.

To prepare phenothiazine S-oxide derivatives, the phenothiazine derivative and the oxidizing agent are used in a molar ratio of generally from 1:0.8 to 1:1.5, preferably from 1:1 to 1:1.3. Oxidizing agents with which no further oxidation to the corresponding S,S-dioxide derivatives occurs, for example H₂O₂, may be used in a larger excess than that specified above in relation to the phenothiazine derivative.

The oxidation is effected generally in a solvent, preferably in a solvent selected from the group consisting of halogenated hydrocarbons and dipolar aprotic solvents, Examples of the former and the latter are, respectively, methylene chloride, and acetonitrile and sulfolane.

Depending on the oxidizing agent, the oxidation to the phenothiazine S-oxide derivatives is effected typically at standard pressure within a temperature range of from −10° C. to +50° C., and the oxidation to the phenothiazine S,S-dioxide derivatives typically at standard pressure within a temperature range of from 0 to +100° C. The reaction time of the oxidation is generally from 0.25 to 24 hours.

The suitable conditions for the oxidation of the particular phenothiazine derivatives to the corresponding phenothiazine S-oxide or phenothiazine S,S-dioxide derivatives can, though, be determined in preliminary experiments in each case by those skilled in the art without any problems. For example, the progress of the oxidation can be monitored with analytical methods, for example by IR spectroscopy.

In a preferred variant, the phenothiazine S-oxide derivatives of the formula I are prepared by oxidizing the corresponding phenothiazine derivatives of the formula I with m-chloroperbenzoic acid as the oxidizing agent in CH₂Cl₂ at from 0 to 20° C.

The phenothiazine S,S-dioxide derivatives of the formula I are preferably prepared by oxidation of the corresponding phenothiazine derivatives of the formula I with m-chloroperbenzoic acid as the oxidizing agent in CH₂Cl₂ at from 0 to 40° C.

The isolation and workup of the resulting phenothiazine S-oxides and phenothiazine S,S-dioxides are effected by processes known to those skilled in the art.

The preparation of the compounds of the formula used in accordance with the invention is shown by way of example hereinbelow. With knowledge of the state of the art, this should make it possible for those skilled in the art to prepare the further compounds used in accordance with the invention.

The compounds of the formula I in which R¹ is hydrogen, alkyl, cyclic alkyl, heterocyclic alkyl, aryl or heteroaryl are prepared advantageously starting from a basic skeleton of the formula 1 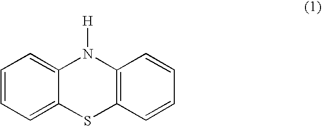
by
aa) N-alkylating or N-arylating the basic skeleton of the formula 1,
ab) halogenating,
ac) coupling reaction with the precursor compounds corresponding to the desired R² and R³ radicals,
ad) oxidation of S to SO or SO₂,
   step aa) being carried out only when R¹ is different from hydrogen (in the remarks below on the preparation of the compounds of the formula I, N-alkylation, N-arylation, N-alkylated and N-arylated refer, with regard to the definition of the R¹ radical, not only to the N-substitution with alkyl radicals but also to the N-substitution with cyclic alkyl radicals and heterocyclic radicals, or not only to the N-substitution with aryl radicals but also to the N-substitution with heteroaryl radicals; in this sense, the appropriate alkyl or aryl reagents for N-alkylation or N-arylation also include cycloalkyl and heterocycloalkyl or heteroaryl reagents).

Suitable reaction conditions for carrying out steps aa), ab), as) and ad) are known to those skilled in the art. Preferred variants of steps aa), ab), ac) and ad) are specified hereinbelow

Step aa)

The N-alkylation or N-arylation is effected preferably by reacting the basic skeleton of the formula 1 with an alkyl halide or aryl halide of the formula R¹-Hal where R¹ has already been defined above and Hal is Cl, Br or I, preferably I. This reaction is performed in the presence of bases which are known to those skilled in the art. They are preferably alkali metal or alkaline earth metal hydroxides such as NaOH, KOH, Ca(OH)₂, alkali metal hydrides such as NaH, KH, alkali metal amides such as NaNH₂, alkali metal or alkaline earth metal carbonates such as K₂CO₃, or alkali metal alkoxides such as NaOMe, NaOEt. Additionally suitable are mixtures of the aforementioned bases. Particular preference is given to NaOH, KOH or NaH.

The N-alkylation (described, for instance, in M. Tosa et al., Heterocycl. Communications, Vol. 7, No. 3, 2001, p. 277-282) or N-arylation (described, for instance, in H. Gilman and D. A. Shirley, J. Am. Chem. Soc. 66 (1944) 888; D. Li et al., Dyes and Pigments 49 (2001) 181-186) is preferably carried out in a solvent. Suitable solvents are, for example, polar aprotic solvents such as dimethyl sulfoxide, dimethylformamide or alcohols. It is likewise possible to use an excess of the alkyl or aryl halide used as a solvent, in which case preference is given to the use of an excess of alkyl or aryl iodides. The reaction may additionally be carried out in a nonpolar aprotic solvent, for example toluene, when a phase transfer catalyst, for example tetra-n-butylammonium hydrogen sulfate, is present (as disclosed, for example in I. Gozlan et al., J. Heterocycl. Chem. 21 (1984) 613-614).

However, the N-arylation may also be effected by copper-catalyzed coupling of the compound of the formula 1 with an aryl halide, preferably an aryl iodide (Ullmann reaction). A suitable process for the N-arylation of phenothiazine in the presence of copper bronze is disclosed, for example, in H. Gilman et al., J. Am. Chem. Soc. 66 (1944) 888-893.

The molar ratio of the compound of the formula 1 to the alkyl halide or aryl halide of the formula R¹-Hal is generally from 1:1 to 1:2, preferably from 1:1 to 1:1.5.

The N-alkylation or N-arylation is carried out typically at standard pressure and within a temperature range of from 0 to 220° C. or to the boiling point of the solvent used. The reaction time extends generally to from 0.5 to 48 hours.

The suitable conditions for the N-alkylation or N-arylation of the compound of the formula 1 can be determined in preliminary experiments in each case by those skilled in the art without any problems. For example, the progress of the N-alkylation or N-arylation can be monitored with analytical methods, for example by IR spectroscopy.

The resulting crude product is worked up by processes known to those skilled in the art.

Step ab)

The halogenation may be carried out by processes known to those skilled in the art. Preference is given to brominating or iodinating in the 3- and 7-position of the optionally N-alkylated or N-arylated basic skeleton of the formula 1.

The basic skeleton of the formula 1 which has optionally been N-alkylated or N-arylated in step aa) can be brominated in the 3- and 7-position of the basic skeleton, for example, according to M. Jovanovich et al. J. Org. Chem. 1984, 49, 1905-1908, by reacting with bromine in acetic acid. In addition, a bromination may be effected according to the process disclosed in C. Bodea et al. Aced. Rep. Rom, 13 (1962) 81-87.

The basic skeleton of the formula 1 which has optionally been N-alkylated or N-arylated in step as) may be iodinated in the 3- and 7-position of the basic skeleton, for example, according to the process disclosed in M. Sailer et al. J. Org. Chem. 2003, 68, 7509-7512. In this process, the corresponding, optionally N-alkylated or N-arylated, 3,7-dibromo-substituted basic skeleton of the formula 1 is initially lithiated and the lithiated product is subsequently iodinated.

The lithiation with a lithium base, for instance n-butyllithium or lithium diisopropylamide, is carried out generally at temperatures of from −78 to +25° C., preferably from −78 to 0° C., more preferably −78° C., by the process known to those skilled in the art. Subsequently, the reaction mixture is warmed to room temperature and worked up by the process known to those skilled in the art

Step ac)

The (nonoxidized) phenothiazine derivatives on which the phenothiazine S-oxide and S,S-dioxide derivatives of the formula I used in accordance with the invention are based are preferably prepared by coupling reactions with precursor compounds which correspond to the desired R² and R³ radicals. Suitable coupling reactions are, for example, the Suzuki coupling or the Yamamoto coupling, of which preference is given to the Suzuki coupling.

Suzuki coupling allows compounds to be prepared which are substituted by the desired R² and R³ radicals at the 3 and 7 positions of the (optionally N-alkylated or N-arylated) basic phenothiazine skeleton of the formula 1 by reacting the corresponding 3,7-halogenated, in particular 3,7-brominated, phenothiazines with boronic acids or boronic esters which correspond to the desired R² and R³ radicals under Pd(0) catalysis and in the presence of a base.

Instead of the boronic acids or boronic esters corresponding to the desired R² and R³ radicals, other boron compounds which bear the desired R² and R³ radicals may also be used in the reaction with the halogenated phenothiazine derivatives. Such boron compounds correspond, for example, to the general formulae R²—B(O—[C(R′)₂]ₙ—O) and R³—B(O—[C(R′)₂]ₙ—O), where R² and R³ are each as defined above and R′ are identical or different radicals and are each hydrogen or C₁-C₂₀-alkyl, such as methyl, ethyl, n-propyl, isopropyl, n-butyl, isobutyl, sec-butyl, tert-butyl, n-pentyl, isopentyl, sec-pentyl, neopentyl, 1,2-dimethylpropyl, isoamyl, n-hexyl, isohexyl, sec-hexyl, n-heptyl, isoheptyl, n-octyl, n-decyl, n-dodecyl or n-octadecyl; preferably C₁-C₁₂-alkyl such as methyl, ethyl, n-propyl, isopropyl, n-butyl, isobutyl, sec-butyl, tert-butyl, n-pentyl, isopentyl, sec-pentyl, neopentyl, 1,2-dimethylpropyl, isoamyl, n-hexyl, isohexyl, sec-hexyl or n-decyl, more preferably C₁-C₄-alkyl such as methyl, ethyl, n-propyl, isopropyl, n-butyl, isobutyl, sec-butyl and tert-butyl, most preferably methyl, and n is an integer from 2 to 10, preferably from 2 to 5.

The boronic acids, boronic esters and boron compounds corresponding to the desired R² and R³ radicals may be prepared by prior art processes or are commercially available. For example, it is possible to prepare the boronic acids and boronic esters by reacting Grignard or lithium reagents with boranes, diboranes or berates.

Suitable Pd(0) catalysts are all customary Pd(0) catalysts. For example, tris(dibenzylideneacetone)dipalladium (0) or tetrakis(triphenylphosphine)palladium(0) may be used. In addition, a Pd(II) salt may be used in a mixture with a ligand, for example Pd(ac)₂ or PdCl₂ and PPh₃, in which case Pd(0) is formed in situ. To carry out the coupling, an excess of PPh₃ may be added. The catalysts are used generally in an amount of from 0.001 to 15 mol %, preferably from 0.01 to 10 mol %, more preferably from 0.1 to 5 mol %, based on the halogenated phenothiazine derivative used.

In the Suzuki coupling, all bases used customarily for this purpose may be used. Preference is given to alkali metal carbonates such as sodium carbonate or potassium carbonate. The base is used generally in a from 2- to 200-fold, preferably a from 2- to 100-fold, more preferably a from 2- to 30-fold molar excess based on the halogenated phenothiazine derivative used.

The component corresponding to the desired R² and R³ radicals (boronic acid, the corresponding boronic ester or the other suitable boron compounds) is used in a ratio of from 100 to 400 mol %, preferably from 100 to 300 mol %, more preferably from 100 to 150 mol %, to the halogenated phenothiazine derivative.

The reaction is effected typically under standard pressure at a temperature of from 40 to 140° C., preferably from 60 to 120° C., more preferably from 70 to 100° C.

The reaction is effected generally with exclusion of oxygen. Typically, the reaction is effected in a solvent, for instance benzene, toluene, tetrahydrofuran, 1,4-dioxane, dimethoxyethane, dimethylformamide, ethanol or petroleum ether. It is likewise possible to use a mixture of tetrahydrofuran, dimethoxyethane or ethanol and water as the solvent.

In a particularly advantageous variant of the process, a halogenated phenothiazine derivative is initially charged in solution under protective gas and admix d with the base which is preferably present in dissolved form (for example in a dimethoxyethane/water mixture and the boronic acids corresponding to the desired R² and R³ radicals. Afterward, the Pd(0) catalyst is added under protective gas. The mixture is stirred at the above-specified temperatures and pressures over a period of generally from 2 to 120 hours, preferably from 4 to 72 hours, more preferably from 6 to 48 hours. Afterward, the reaction mixture is worked up by the processes known to those skilled in the art.

In addition, compounds may be prepared which are substituted by the desired R² and R³ radicals at the 3 and 7 positions of the (optionally N-alkylated or N-arylated) basic phenothiazine skeleton of the formula 1, by reacting the corresponding 3,7-halogenated, in particular 3,7-brominated, phenothiazines under Ni(0) catalysis with halogen compounds, in particular bromine compounds, which correspond to the desired R² and R³ radicals (Yamamoto couplings).

In the Yamamoto coupling, preference as given to preparing, with exclusion of oxygen, a solution, preferably a DMF solution, of the catalyst from an Ni(0) compound, preferably Ni(COD)₂, and bipyridyl in equimolar amounts. The halogenated, preferably brominated, phenothiazine derivative and the halogen compounds, especially bromine compounds, corresponding to the desired R² and R³ radicals are added with exclusion of oxygen to this solution in a solvent, preferably toluene.

The reaction conditions in the preparation of the phenothiazine derivatives by means of Yamamoto coupling, such as temperature, pressure, solvent and ratio of the halogenated, preferably brominated, phenothiazine derivative to the components corresponding to the R² and R³ radicals correspond to those of the Suzuki coupling.

Suitable Ni(0) compounds for preparing the catalyst are all customary Ni(0) compounds. For example, Ni(C₂H₄)₃, Ni(1,5-cyclooctadiene)₂ (“Ni(COD)₂”), Ni(1,6-cyclodecadiene)₂ or Ni(1,5,9-all-trans-cyclododecatriene)₂ may be used. The catalysts are used generally in an amount of from 1 to 100 mol %, preferably from 5 to 80 mol %, more preferably from 10 to 70 mol %, based on the halogenated phenothiazine derivative used.

Suitable process conditions and catalysts, especially for the Suzuki coupling, are disclosed, for example, in Suzuki-Miyaura cross-coupling: A. Suzuki, J. Organomet. Chem. 576 (1999) 147-168, B-alkyl Suzuki-Miyaura cross-coupling: S. R. Chemler et al., Angew. Chem. 2001, 113, 4676-4701 and the literature cited therein.

Step ad)

Preferred oxidizing agents and process conditions for oxidizing the phenothiazines to the corresponding phenothiazine S,S-dioxide derivatives are specified above and are disclosed, for example, in M. Tosa et al., Heterocyclic Commun. 7 (2001) 277-232.

The compounds of the formula I in which R¹ is a moiety of the formula I or III are prepared advantageously starting from a basic skeleton of the formula 1 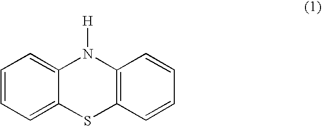
by
ba) halogenating,
bb) separate coupling reactions with the precursor compounds corresponding to the desired R² and R³ radicals and R⁴ and R⁵ radicals and R⁷ and R⁸ radicals respectively,
bc) N-arylating the phenothiazines substituted by the desired R² and R³ radicals and R⁴ and R⁵ radicals and R⁷ and R⁸ radicals with the compounds corresponding to the 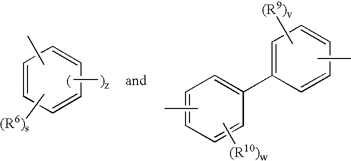
   groups,
bd) oxidizing the S to SO or SO₂.

Suitable reaction conditions for carrying out steps be), bb) and bd) have already been laid out in detail above for the corresponding reaction steps ab), ac) and ad).

Step bc) is advantageously carried out in analogy to step as). In this reaction, the 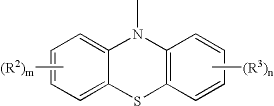
unit is joined to the unit the two units
and 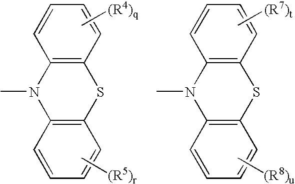
via the corresponding phenylene or biphenylyl unit 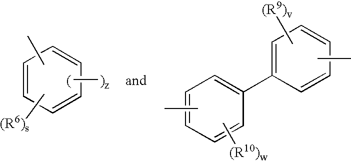
by copper-catalyzed coupling of the compounds of the formulae 1a and 1b 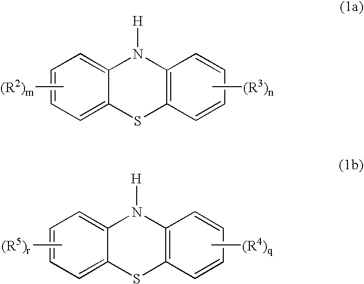
with the corresponding aryl halide, preferably the aryl iodide, of the formula 2 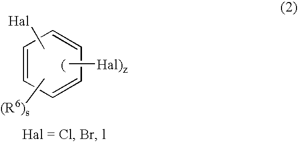
or
by copper-catalyzed coupling of the compounds of the formulae 1a and 1c 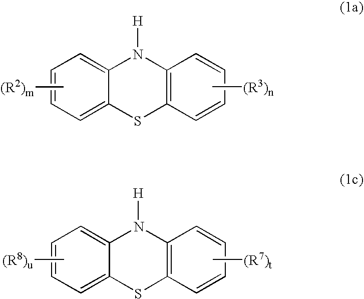
with the corresponding aryl dihalide, preferably the aryl diiodide, of the formula 3

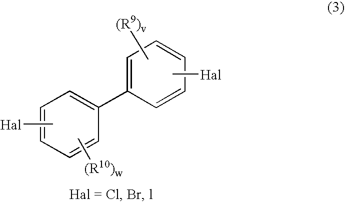

When the intention is to prepare the symmetrical compounds 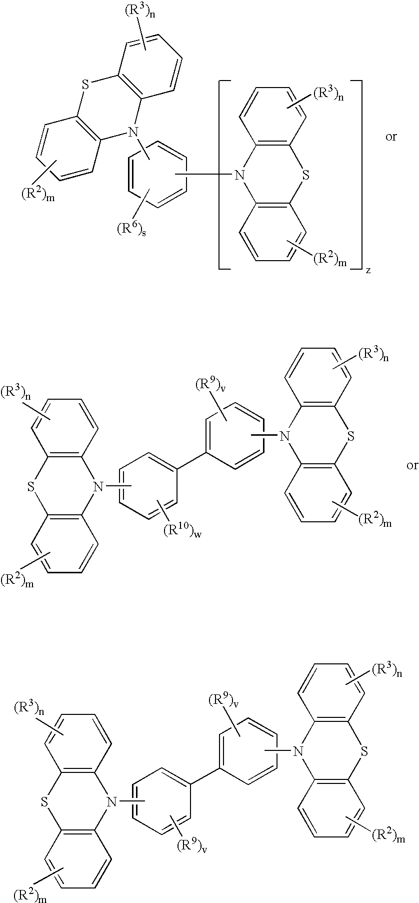
the procedure may, taking into account the stoichiometry of the reactants, be based on the N-arylation of phenothiazine in the presence of copper bronze according to H. Gilman et al., J. Am. Chem. Soc. 66 (1944) 888-893.

In the case of different phenothiazine derivatives of the formulae 1a and 1b, for example where z=1, this procedure leads to PT¹-phen-PT¹, PT¹-phen-PT², PT²-phen PT² product mixtures, where PT¹ and PT² are in each case a different phenothiazine unit which derives from the corresponding compounds of the formulae 1a and 1b, and phen is an optionally substituted phenylene unit which derives from the corresponding compound of the formula 2. When the phen unit is additionally unsymmetric, the number of different compounds in the product mixture increases, since the isomeric compound PT phen-PT¹ is then also present apart from the compound PT¹-phen-PT².

In the case of different phenothiazine derivatives of the formulae 1a and 1, the situation is similar, where the compounds PT¹-biphen-PT¹, PT¹-biphen-PT³ and PT³-biphen-PT³ are obtained, and, in the case of an unsymmetric biphen unit, additionally the compound PT³-biphen-PT¹ which is isomeric to PT¹-biphen-PT³. PT¹ and PT³ are each a different phenothiazine unit which derives from the corresponding compounds of the formulae 1a and 1c, and biphen is an optionally substituted biphenylyl unit which derives from the corresponding compound of the formula 3.

However, it is possible by suitable process control to increase the yield of desired product. For example, the aryl halide or biphenyl dihalide, if appropriate dissolved in an inert solvent, may be initially charged together with the copper powder and the first phenothiazine (PT¹-H), if appropriate likewise dissolved in the same inert solvent, may be added. As a result of this, the PT¹-phen-Hal or PT¹-biphen-Hal product is formed predominantly and is then reacted in the subsequent step with the second phenothiazine derivative (PT²-H or PT³-H) to give the PT¹-phen-PT² (when z=1) or PT¹-biphen-PT³ product. However, the formation of the isomeric products PT²-phen-PT¹ or PT³-biphen-PT¹ cannot normally be influenced by such a procedure.

With regard to the reaction conditions, reference will be made to the preparation of the symmetric compounds for the aforementioned procedure. Taking into account the further prior art, the suitable conditions thus become apparent to those skilled in the art, if appropriate with performance of additional preliminary experiments, without a great amount of time and effort.

Alternatively, in step bc), a base-catalyzed reaction of the compounds of the formulae 1a and 1b 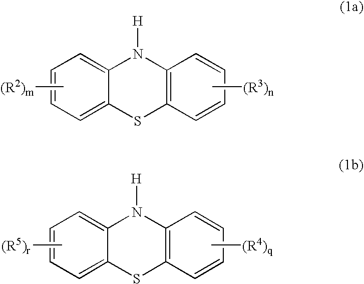
with the appropriate aryl fluoride of the formula 2′ 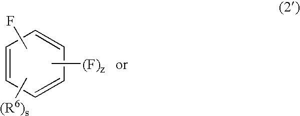
a base-catalyzed reaction of the compounds of the formulae 1a and 1c 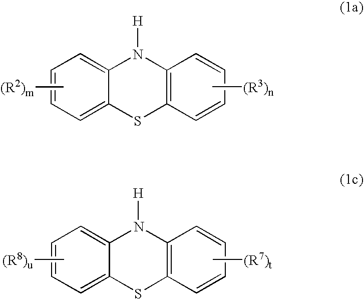
with the appropriate aryl difluoride of the formula 3′ 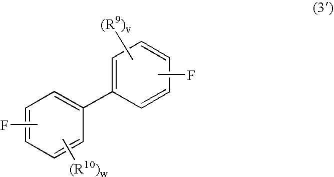
may be effected. Useful bases in this reaction are the compounds specified under step aa). An especially suitable base is NaH

The compounds of the formulae 1a and 1b or 1a and 1c deprotonated by means of base then react under nucleophilic aromatic substitution with the compounds of the formulae 2′ or 3′. With regard to the preparation of the symmetric and unsymmetric compounds of the formula I in which R¹ are moieties of the formulae II or III, reference is made mutatis mutandis to the remarks above.

The compounds of the formula I in which R¹ is a moiety of the formula IV are prepared advantageously starting from a basic skeleton of the formula 1 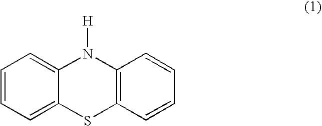
by
ca) halogenating,
cb) separate coupling reactions with the precursor compounds corresponding to the desired R² and R³ radicals and R⁴ and R⁵ radicals and R⁷ and R⁸ radicals respectively,
cc) N-alkylating the phenothiazines substituted by the desired R² and R³ radicals and R⁴ and R⁵ radicals and R⁷ and R⁸ radicals with the compound corresponding to the 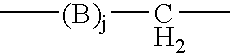
   group,
cd) oxidizing the S to SO or SO₂.

Suitable reaction conditions for carrying out steps ca), cb) and cd) have already been laid out in detail above for the corresponding reaction steps ab), so) and ad).

Step cc) is carried out in analogy to the N-alkylation as described under step aa).

With regard to the preparation of the symmetric and unsymmetric compounds of the formula I in which R¹ is a moiety of the formula IV, reference is likewise made mutatis mutandis to the above remarks.

The oxidation step performed last in the above-specified preparation process, in which the sulfur of the phenothiazine skeleton is converted to the SO or SO₂ group, may of course also be carried out at an earlier time. Accordingly, in a modification of the preparation process specified, the starting materials may also be compounds of the formula 1′ 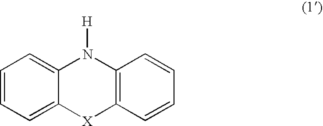
in which X is an SO or SO₂ group.

The compounds of the formula I are outstandingly suitable for use as matrix materials in organic light-emitting diodes (OLEDs). In particular, they are highly suitable as matrix materials in the light-emitting layer of OLEDs.

The present invention therefore further provides for the use of the compounds of the formula I as matrix materials in the light-emitting layer of organic light-emitting diodes.

The use of the compounds of the formula I as matrix materials rules out the possibility that these compounds also emit light themselves. However, the matrix materials used in accordance with the invention have the effect that an increase in the illumination density and quantum yield over otherwise customary matrix materials is achieved normally in the case of compounds which are used as emitters in OLEDs when they are embedded in the former.

Many of these emitter compounds are based on metal complexes, and especially the complexes of the metals Ru, Rh, Ir, Pd and Pt, in particular the complexes of the Ir, have gained significance. The compounds of the formula I used in accordance with the invention are particularly suitable as matrix materials for emitters based on such metal complexes. They are especially suitable for use as matrix materials together with complexes of Ru, Rh, Ir, Pd and Pt, more preferably for use together with complexes of Ir.

Suitable metal complexes for use together with the compounds of the formula I as matrix materials in OLEDs are described for example, in documents WO 02/60910 A1, WO 02/68453 A1, US 2001/0015432 A1, US 2001/0019782 A1, US 2002/0055014 A1, US 2002/0024293 A1, US 2002/0048689 A1, EP 191 612 A2, EP 1 191 613 A2, EP 1 211 257 A2, US 2002/0094453 A1, WO 02/02714 A2, WO 00/70655 A2, WO 01/41512 A1 and WO 02/15645 A1.

Suitable metal complexes for use together with the compounds of the formula I as matrix materials in OLEDs are, for example, also carbene complexes as described in the prior international application PCT/EP/04/09269. Reference is made exclusively to the disclosure content of this application and this disclosure content is incorporated by reference into the contents of the present application. In particular, suitable metal complexes for use together with the compounds of the formula I as matrix materials in OLEDs comprise carbene ligands of the following structures disclosed in the prior International application PCT/EP/04/09269 (the definition of the variables was taken from the application PCT/EP/04/09269; with regard to the more precise definition of the variables, reference is made explicitly to this application): 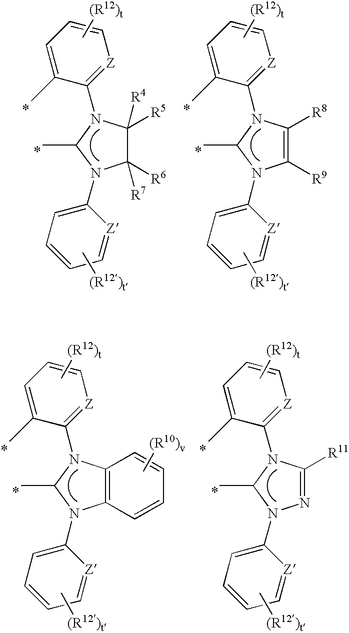
where:
* are the binding sites of the ligand to the metal center;
z, z′ are the same or different and are each CH or N;
R¹², R^{12′} are the same or different and are each an alkyl aryl, heteroaryl or alkenyl radical, preferably an alkyl or aryl radical, or in each case 2 R¹² or R^{12′} radicals together form a fused ring which may optionally contain at least one heteroatom, preferably N; preferably, in each case 2 R¹² and R^{12′} radicals together form a fused aromatic G ring, and one or more further aromatic rings may optionally be fused to this preferably six-membered aromatic ring, any conceivable fusion being possible, and the fused radicals may in turn be substituted; or R¹² or R^{12′} is a radical having donor or acceptor action, preferably selected from the group consisting of halogen radicals, preferably F, Cl, Br, more preferably F; alkoxy, aryloxy, carbonyl, ester, amino groups, amide radicals, CHF₂, CH₂F, CF₃, CN, thio groups and SCN;
t and t′ are the same or different, preferably the same, and are from 0 to 3, where, when t or t′ is >1, the R¹² and R^{12′} radicals may be the same or different; preferably, t or t′ is 0 or 1, the R¹² or R^{12′} radical is disposed, when t or t′ is 1, in the ortho-, meta- or para-position to the attachment site with the nitrogen atom adjacent to the carbene carbon atom;
R⁴, R⁵, R⁶,
R⁷, R⁸, R⁹
and R¹¹ are each hydrogen, alkyl aryl, heteroaryl, alkenyl or a substituent having donor or acceptor action, preferably selected from halogen radicals preferably F, Cl, Br, more preferably F, alkoxy radicals, aryloxy radicals, carbonyl radicals, ester radicals, amine radicals, amide radicals, CH₂F groups, OHF₂ groups, CF₃ groups, CN groups, thio groups and SCN groups, preferably hydrogen, alkyl, heteroaryl or aryl,
R¹⁰ is alkyl, aryl, heteroaryl or alkenyl, preferably alkyl, heteroaryl or aryl, or in each case 2 R¹⁰ radicals together form a fused ring which may optionally contain at least one heteroatom, preferably nitrogen; preferably, in each case 2 R¹⁰ radicals together form a fused aromatic C₆ ring, and one or more further aromatic rings may be fused to this preferably six-membered aromatic ring, any conceivable fusion being possible, and the fused radicals may in turn be substituted; or R¹⁰ is a radical having donor or acceptor action, preferably selected from the group consisting of halogen radicals, preferably F, Cl, Br, more preferably F; alkoxy, aryloxy, carbonyl, ester, amino groups, amide radicals, CHF₂, CH₂F, CF₃, CN, thio groups and SCN
v is from 0 to 4, preferably 0, 1 or 2, most preferably 0, where, when v is 0, the four carbon atoms of the aryl radical in formula c which are optionally substituted by R¹⁰ bear hydrogen atoms.
   in particular, suitable metal complexes for use together with the compounds of the formula I as matrix materials in OLEDs comprise Ir-carbene complexes of the following structures disclosed in the prior international patent application PCT/EP/04/09269. 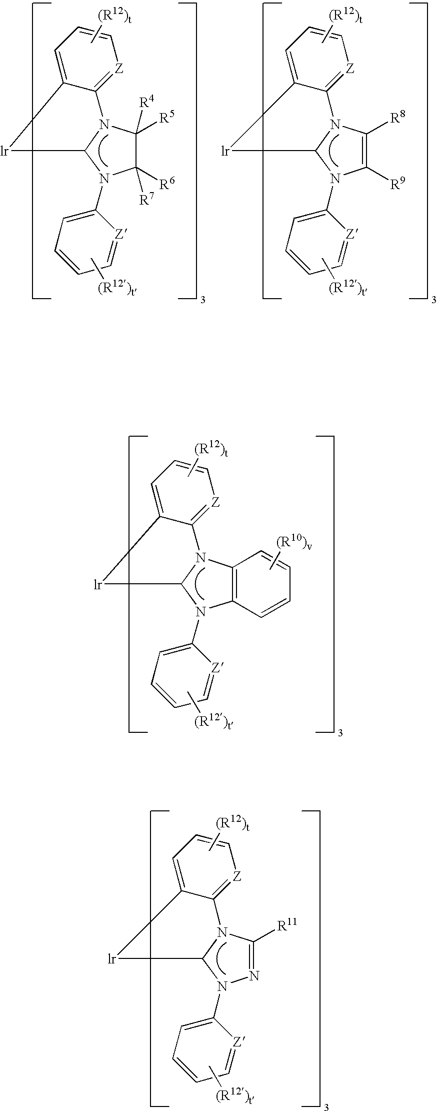
   where the variables are each as defined above.

Further suitable metal complexes for use together with the compounds of the formula I as matrix materials in OLEDs are in particular also. 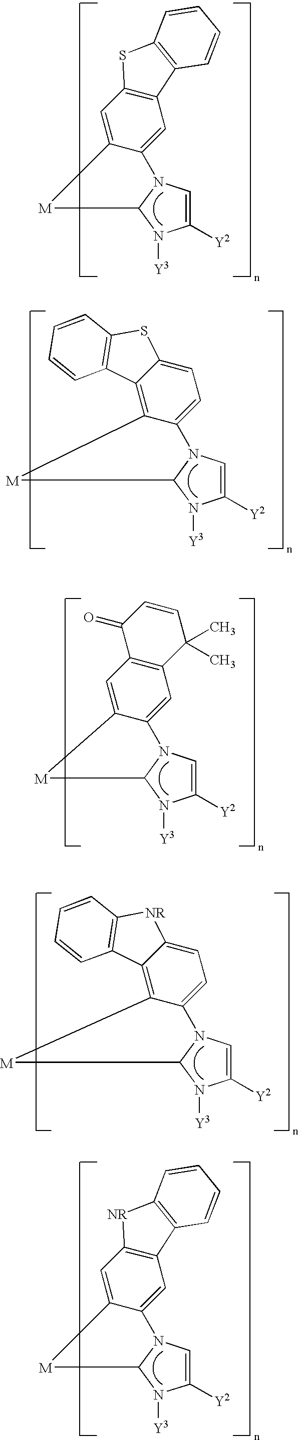 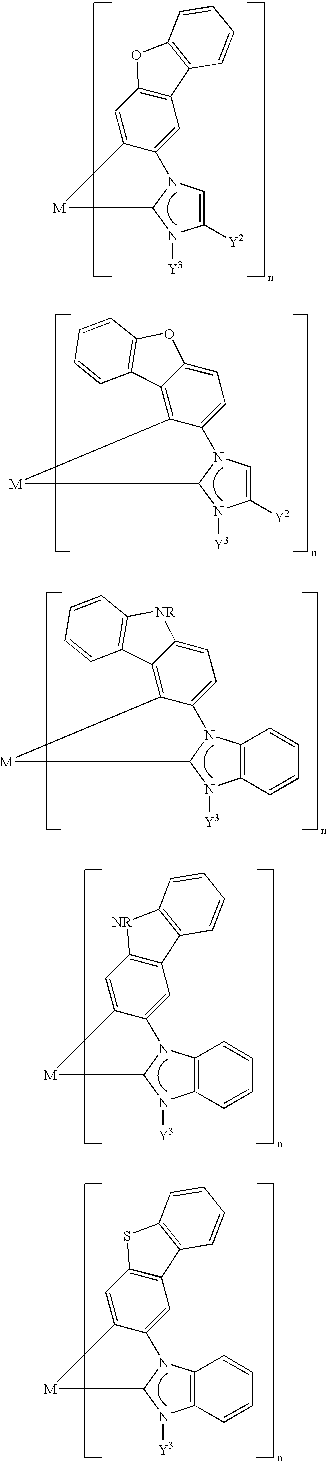 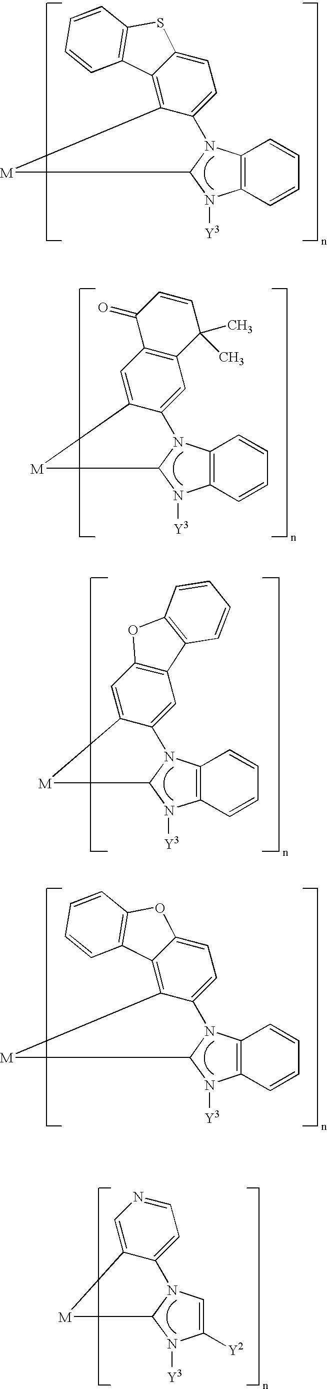 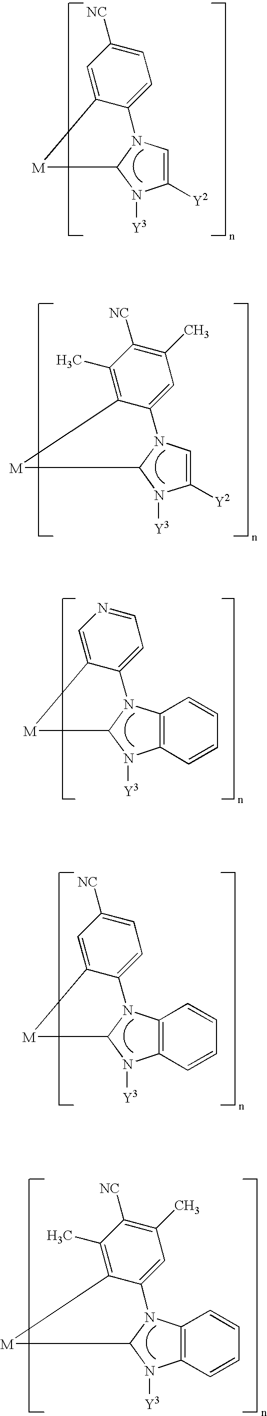 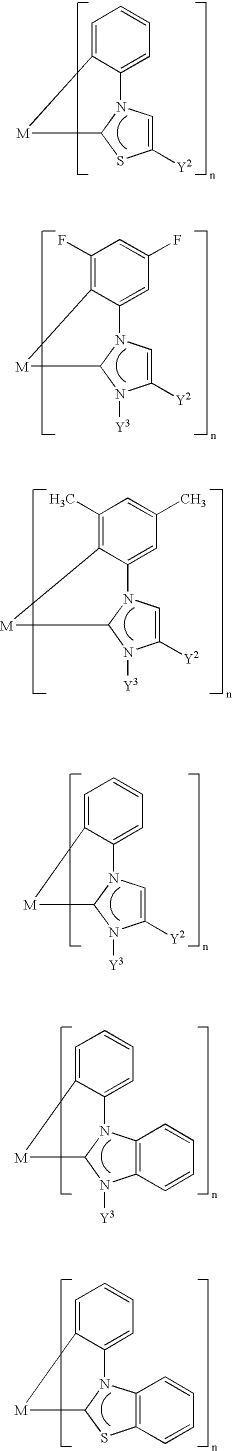 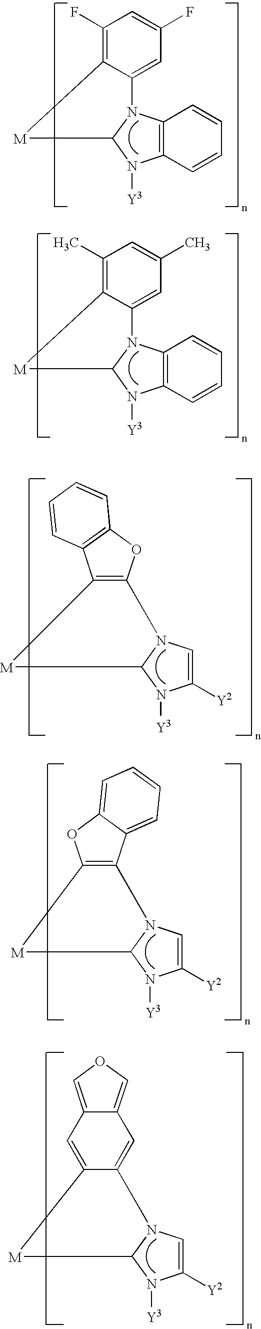 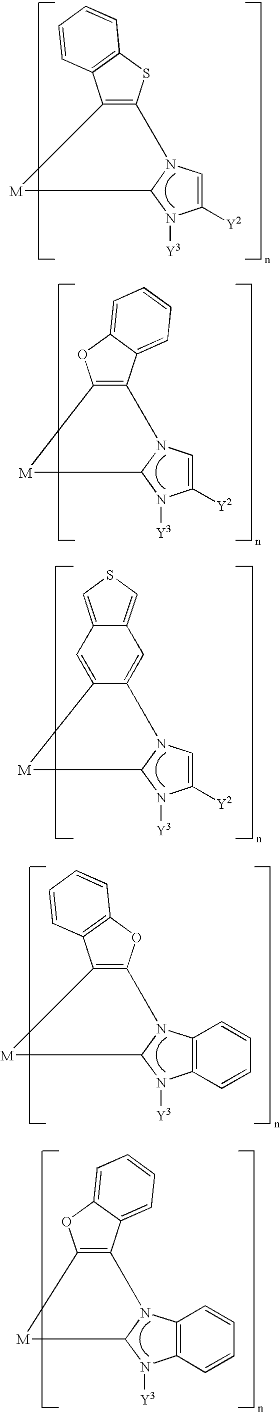 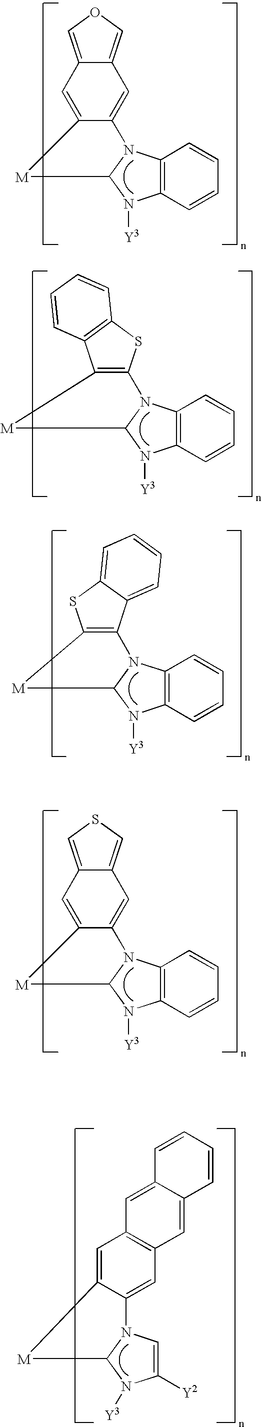 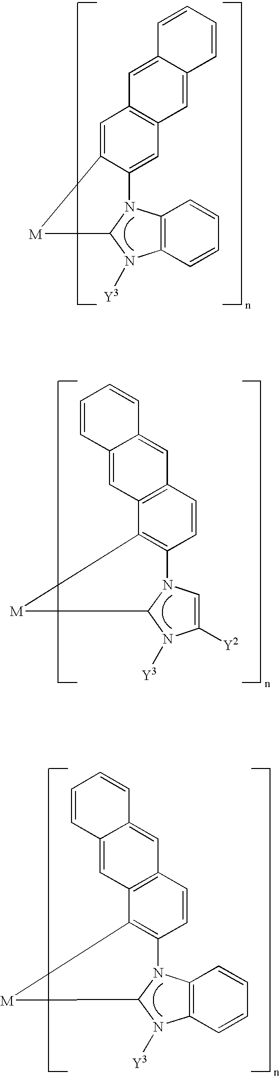
where M is Ru (III), Rh(III), Ir(III), Pd(II) or Pt(II), n assumes the value of 3 for Ru(III), Rh(III) and Ir(III), and the value of 2 for Pd(II) and Pt(II), and Y² and Y³ are each hydrogen, methyl, ethyl, n-propyl, isopropyl or tert-butyl. M is preferably Ir(III) where n=3 Y³ is preferably methyl, ethyl, n-propyl, isopropyl or tert-butyl.

Further suitable metal complexes for use together with the compounds of the formula I as matrix materials in OLEDs are in particular also: 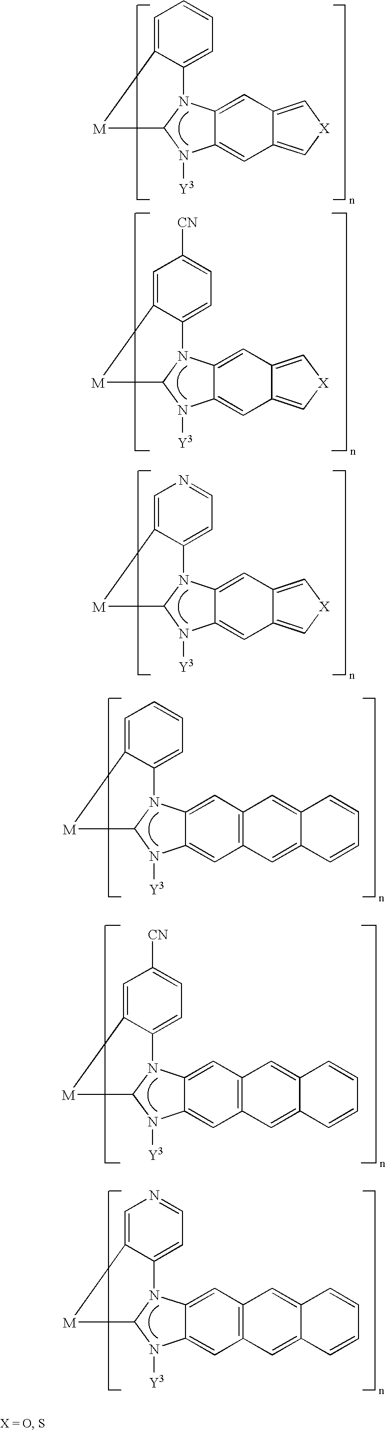 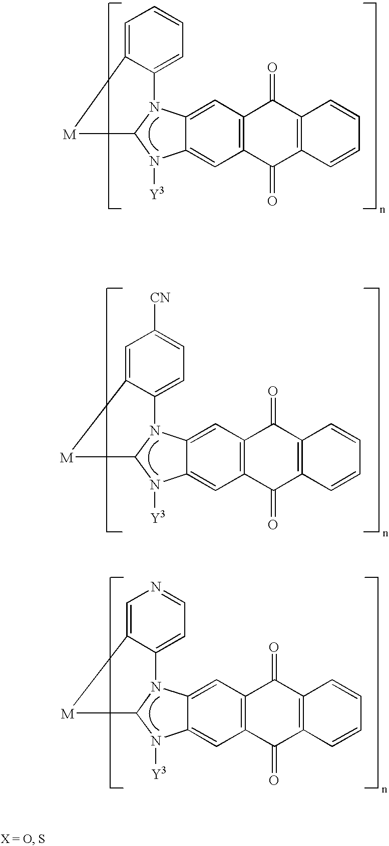
where M is Ru(III), Rh(III), Ir(III), Pd(II) or Pt(II), n assumes the value of 3 for Ru(III), Rh(III) and Ir(III), and the value of 2 for Pd(II) and Pt(II), and Y³ is hydrogen, methyl, ethyl, n-propyl, isopropyl or tert-butyl. M is preferably Ir(III) where n=3. Y³ is preferably methyl, ethyl, n-propyl, isopropyl or tert-butyl.

Further suitable metal complexes for use together with the compounds of the formula I as matrix materials in OLEDs are in particular also: 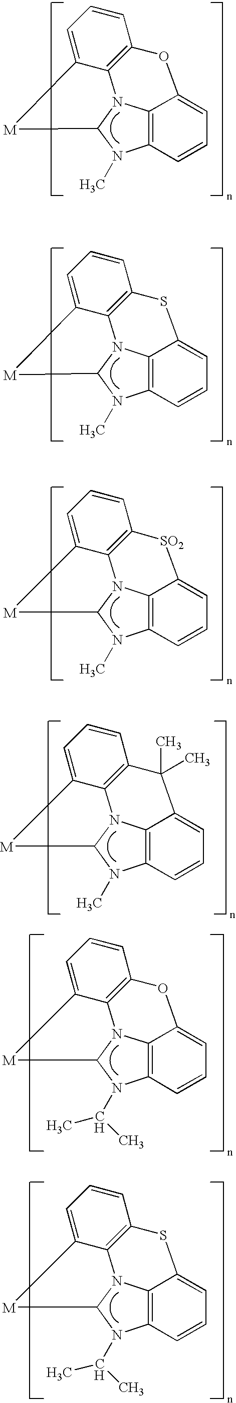 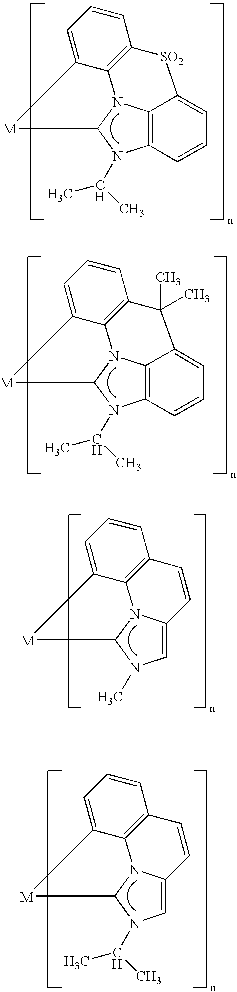
where M is Ru(III), Rh(III) and in particular Ir(III), Pd(II) or Pt(II), n assumes the value of 3 for Ru(III), Rh(III) and Ir(III) and the value of 2 for Pd(II) and Pt(II).

Further suitable metal complexes for use together with the compounds of the formula I as matrix materials in OLEDs are in particular also: 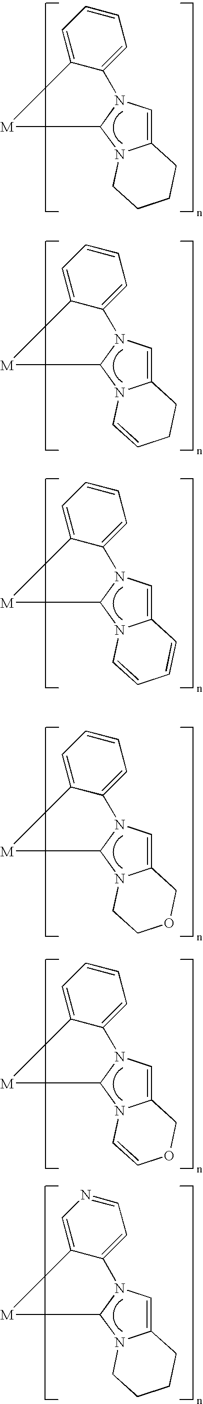 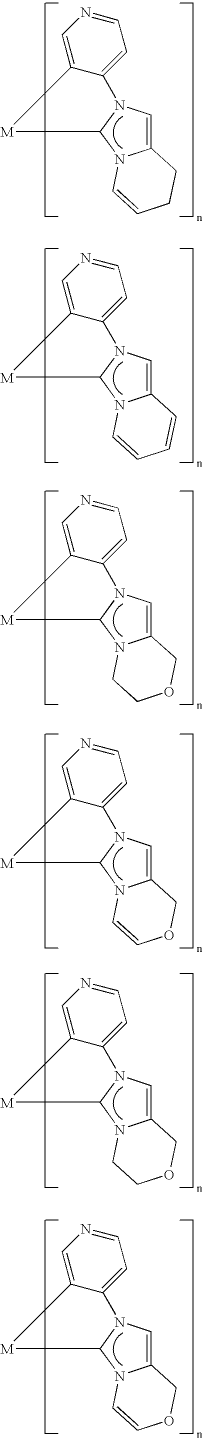 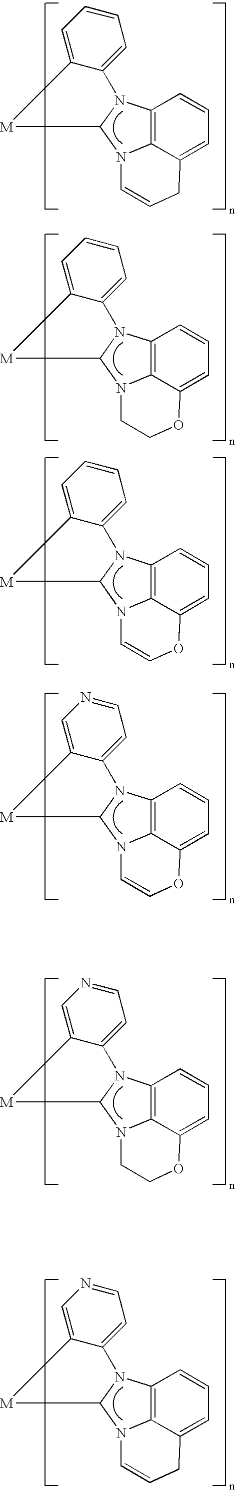 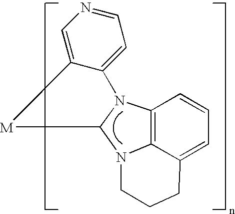
where M is Ru(III), Rh(III) and in particular Ir(III), Pd(II) or Pt(II), n assures the value of 3 or Ru(III), Rh(III) and Ir(III), and the value of 2 for Pd(II) and Pt(II).

In addition, useful complexes are also those having different carbene ligands and/or having ligands L, the latter being mono- or dianionic and either mono- or bidentate.

With reference to the table below, complexes ML′(L″)₂ having trivalent metal centers and two different carbene ligands L′ and L″ are specified schematically

| L′ | L″ |
|---|---|
| L¹ | L² |
| L¹ | L³ |
| L¹ | L⁴ |
| L¹ | L⁵ |
| L¹ | L⁶ |
| L¹ | L⁷ |
| L² | L³ |
| L² | L⁴ |
| L² | L⁵ |
| L² | L⁶ |
| L² | L⁷ |
| L³ | L⁴ |
| L³ | L⁵ |
| L³ | L⁶ |
| L³ | L⁷ |
| L⁴ | L⁵ |
| L⁴ | L⁶ |
| L⁴ | L⁷ |
| L⁵ | L⁶ |
| L⁵ | L⁷ |
| L⁶ | L⁷ |
| L⁷ | L⁶ |
| L⁷ | L⁵ |
| L⁷ | L⁴ |
| L⁷ | L³ |
| L⁷ | L² |
| L⁷ | L¹ |
| L⁶ | L⁵ |
| L⁶ | L⁴ |
| L⁶ | L³ |
| L⁶ | L² |
| L⁶ | L¹ |
| L⁵ | L⁴ |
| L⁵ | L³ |
| L⁵ | L² |
| L⁵ | L¹ |
| L⁴ | L³ |
| L⁴ | L² |
| L⁴ | L¹ |
| L³ | L² |
| L³ | L¹ |
| L² | L¹ |

where M is, for example, Ru(III), Rh(III) or Ir(III), in particular Ir(III), and L′ and L″ are each, for example, ligands selected from the group of ligands L¹ to L⁷ 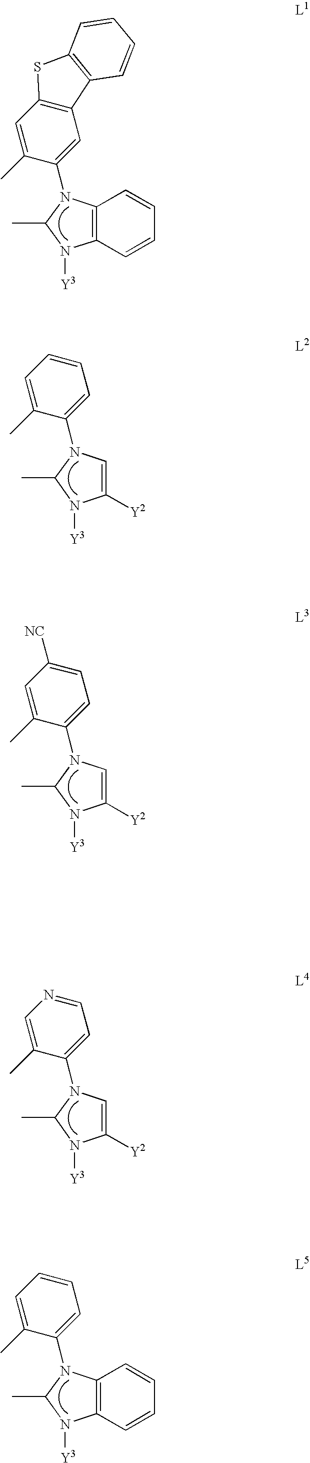 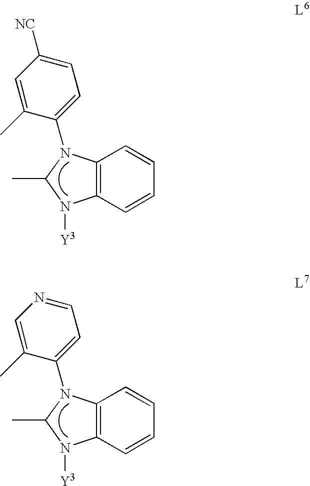
Y² is hydrogen, methyl, ethyl, n-propyl, isopropyl or tert-butyl, and Y³ is methyl, ethyl, n-propyl, isopropyl or tert-butyl.

One example of a representative of these complexes having different carbene ligands (L′=L⁴ where Y²=hydrogen and Y³=methyl; L″=L² where Y²=hydrogen and Y³=methyl) is:

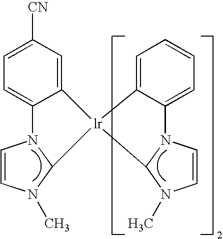

Of course, it is also possible for all three carbene ligands in the complexes, used as emitters in the matrix materials of the formula I, of trivalent metal centers (for instance in the case of Ru(III), Rh(III) or Ir(III)) to be different.

Examples of complexes of trivalent metal centers M with ligands L (here, monoanionic, bidentate ligand) as “spectator ligands” are LML′L″, LM(L′)₂ and L₂ML′, where M is, for instance, Ru(III), Rh(III) or Ir(III), in particular Ir(III), and L′ and L″ are each as defined above. For the combination of L′ and L″ in the complexes LML′L″, this gives:

| L′ | L″ |
|---|---|
| L¹ | L² |
| L¹ | L³ |
| L¹ | L⁴ |
| L¹ | L⁵ |
| L¹ | L⁶ |
| L¹ | L⁷ |
| L² | L³ |
| L² | L⁴ |
| L² | L⁵ |
| L² | L⁶ |
| L² | L⁷ |
| L³ | L⁴ |
| L³ | L⁵ |
| L³ | L⁶ |
| L³ | L⁷ |
| L⁴ | L⁵ |
| L⁴ | L⁶ |
| L⁴ | L⁷ |
| L⁵ | L⁶ |
| L⁵ | L⁷ |
| L⁶ | L⁷ |

Useful ligands L are in particular acetylacetonate and derivatives thereof, picolinate, Schiff bases, amino acids and the bidentate monoanionic ligands specified in WO 02/15645; in particular, acetylacetonate and picolinate are of interest. In the case of the complexes L₂ML′, the ligands L may be the same of different.

One example of these complexes having different carbene ligands (L′=L⁴ where Y²=hydrogen and Y³=methyl; L″=L² where Y²=hydrogen and Y³=methyl) is: 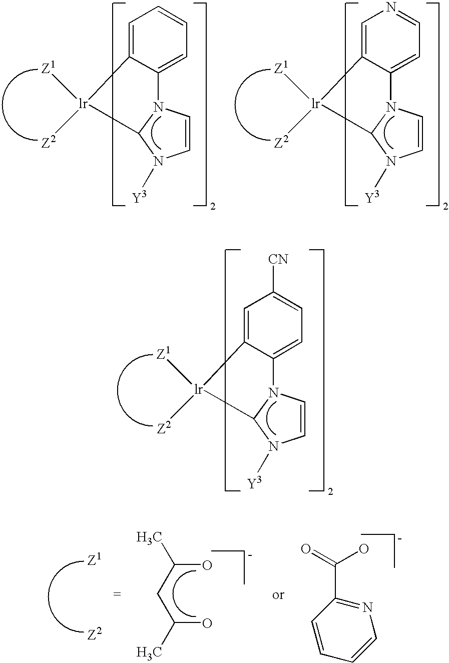
where z¹ and z² in the symbol 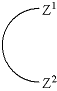
represent both “teeth” of the ligand L. Y³ is hydrogen, methyl, ethyl, n-propyl, isopropyl or tert-butyl, in particular methyl, ethyl, n-propyl or isopropyl.

The present invention therefore provides organic light-emitting diodes comprising a light-emitting layer which comprises at least one compound of the formula I as a matrix material and at least one further substance distributed therein as an emitter.

The present invention further additionally provides a light-emitting layer which comprises at least one compound of the formula I as a matrix material and at least one further substance distributed therein as an emitter.

In particular, the present invention further provides a light-emitting layer which consisting of one or more compounds of the formula I as a matrix material and at least one further substance distributed therein as an emitter.

Organic light-emitting diodes (OLEDs) are in principle formed from a plurality of layers, for example:

1. anode

2. hole-transporting layer

3. light-emitting layer

4. electron-transporting layer

5. cathode

Layer sequences different from the above-specified structure are also possible and are known to those skilled in the art. For example, it is possible that the OLED does not have all of the layers specified; for example, an OLED having the layers (1) (anode), (3) (light-emitting layer) and (5) (cathode) is likewise suitable, in which case the function of the layers (2) (hole-transporting layer) and (4) (electron-transporting layer) are assumed by the adjacent layers. OLEDs which have the layers (1), (2), (3) and (5), or the layers (1), (3), (4) and (5), are likewise suitable.

The phenothiazine S-oxide and phenothiazine S,S-dioxide derivatives of the formula I may be used as charge-transporting, in particular hole-transporting, materials, but they preferably find use as matrix materials in the light-emitting layer.

The phenothiazine S-oxide or phenothiazine S,S-dioxide derivatives of the formula I used in accordance with the invention may be present in the light-emitting layer as the sole matrix material, without further additives. However, it is likewise possible that further compounds are present in the light-emitting layer in addition to the phenothiazine S-oxide or phenothiazine S,S-dioxide derivatives of the formula I used in accordance with the invention. For example, a fluorescent dye may be present in order to change the emission color of the emitter molecule present. In addition, a diluent material may be added. This diluent material may be a polymer, for example poly(N-vinylcarbazole) or polysilane. However, the diluent material may likewise be a small molecule, for example 4, 4′-N,N′-dicarbazolebiphenyl (CBP=CDP) or tertiary aromatic amines. When a diluent material is used, the proportion of the phenothiazine S-oxide or phenothiazine S,S-dioxide derivatives of the formula I used in accordance with the invention in the light-emitting layer is generally still at least 40% by weight, preferably from 50 to 100% by weight, based on the total weight of phenothiazine S-oxide or phenothiazine S,S-dioxide derivatives and diluents.

The individual aforementioned layers of the OLED may be composed of 2 or more layers. For example, the hole-transporting layer may be composed of one layer into which holes are injected from the electrode and one layer which transports the holes from the hole-injecting layer away into the light-emitting layer. The electron-transporting layer may likewise consist of a plurality of layers, for example one layer in which electrons are injected by the electrode and one layer which receives electrons from the electron-injecting layer and transports them into the light-emitting layer. These specified layers are each selected according to factors such as energy level, thermal resistance and charge carrier mobility, and also energy differential of the layers mentioned with the organic layers or the metal electrodes. Those skilled in the art are capable of selecting the structure of the OLED in such a way that it is adapted optimally to the organic compounds used as emitter substances in accordance with the invention.

In order to obtain particularly efficient OLEDs, the HOMO (highest occupied molecular orbital) of the hole-transporting layer should be aligned to the work function of the anode, and the LUMO (lowest unoccupied molecular orbital) of the electron-transporting layer aligned to the work function of the cathode.

The present application further provides an OLED comprising a light-emitting layer which comprises at least one compound of the formula I as a matrix material and at least one further substance distributed therein as an emitter, or which consists of one or more compounds of the formula I as a matrix material and at least one further substance distributed therein as an emitter.

The anode (1) is an electrode which provides positive charge carriers. It may be composed, for example, of materials which comprise a metal, a mixture of different metals, a metal alloy, a metal oxide or a mixture of different metal oxides. Alternatively, the anode may be a conductive polymer. Suitable metals include the metals of groups Ib, IVa, Va and VIa of the Periodic Table of the Elements, and also the transition metals of group VIIIa. When the anode is to be transparent, mixed metal oxides of groups IIb, IIIb and IVb of the Periodic Table of the Elements (old IUPAC version) are generally used, for example indium tin oxide (ITO). It is likewise possible that the anode (1) comprises an organic material, for example polyaniline, as described, for example, in Nature, Vol. 357, pages 477 to 479 (Jun. 11, 1992). At least either the anode or the cathode should be at least partly transparent in order to be able to couple out the light formed.

Suitable hole-transporting materials for the layer (2) of the inventive OLED are disclosed, for example, in Kirk-Othmer Encyclopedia of Chemical Technology, 4th Edition, Vol. 18, pages 837 to 860, 1996. Either hole-transporting molecules or polymers may be used as the hole-transporting material. Customarily used hole-transporting molecules are selected from the group consisting of 4,4′-bis[N-(1-naphthyl)-N-phenylamino]biphenyl (α-NPD), N,N′-diphenyl-N,N′-bis(3-methylphenyl)-[1,1′-biphenyl]-4,4′-diamine (TPD), 1,1-bis[(di-4-tolylamino)phenyl]cyclohexane (TAPC), N,N′-bis(4-methylphenyl)-N,N′-bis(4-ethylphenyl-[1,1′-(3,3′-dimethyl)biphenyl]-4,4′-diamine (ETPD), tetrakis(3-methylphenyl)-N,N,N′,N′-2,5-phenylenediamine (PDA), α-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), 1-phenyl-3-[p-(diethylamino)styryl]-5-[p-(diethylamino)phenyl]pyrazoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), 4,4′,4″-tris(N,N-diphenylamino)triphenylamine (TDTA), porphyrin compounds and phthalocyanines such as copper phthalocyanines. Customarily used hole-transporting polymers are selected from the group consisting of polyvinylcarbazoles, (phenylmethyl)polysilanes and polyanilines. It is likewise possible to obtain hole-transporting polymers by doping hole-transporting molecules into polymers such as polystyrene and polycarbonate. Suitable hole-transporting molecules are the molecules already mentioned above.

Suitable electron-transporting materials for the layer (4) of the inventive OLEDs include metals chelated with oxinoid compounds, such as tris(8-quinolinolato)aluminum (Alq3), compounds based on phenanthroline such as 2,9-dimethyl-4,7-diphenyl-1,10-phenanthroline (DDPA=BCP) or 4,7-diphenyl-1,10-phenanthroline (DPA) and azole compounds such as 2-(4-biphenylyl)-5-(4-t-butylphenyl)-1,3,4-oxadiazole (PBD) and 3-(4-biphenylyl)-4-phenyl-5-(4-t-butylphenyl)-1,2,4-triazole (TAZ). The layer (4) may serve both to ease the electron transport and as a buffer layer or as a barrier layer in order to prevent quenching of the exciton at the interfaces of the layers of the OLED. The layer (4) preferably improves the mobility of the electrons and reduces quenching of the exciton.

Of the materials specified above as hole-transporting materials and electron-transporting materials, some can fulfill a plurality of functions. For example, some of the electron-conducting materials are simultaneously hole-blocking materials when they have a low-lying HOMO.

The charge transport layers may also be electronically doped in order to improve the transport properties of the materials used, in order firstly to make the layer thicknesses more generous (avoidance of pinholes/short circuits) and secondly to minimize the operating voltage of the device. For example, the hole-transporting materials may be doped with electron acceptors; for example, phthalocyanines or arylamines such as TPD or TDTA may be doped with tetrafluorotetracyanoquinodimethane (F4-TCNQ). The electron-transporting materials may, for example, be doped with alkali metals, for example Alq₃ with lithium Electronic doping is known to those skilled in the art and is disclosed, for example, in W. Gao, A. Kahn, J. Appl. Phys., Vol. 94, No. 1, Jul. 1, 2003 (p-doped organic layers) and A. G. Werner, F. Li, K. Harada, M. Pfeiffer, T. Fritz, K. Leo, Appl. Phys. Lett., Vol. 82, No, 25, Jun. 23, 2003 and Pfeiffer et al., Organic Electronics 2003, 4, 89-103.

The cathode (5) is an electrode which serves to introduce electrons or negative charge carriers. Suitable materials for the cathode are selected from the group consisting of alkali metals of group Ia, for example Li, Cs, alkaline earth metals of group IIa, for example calcium, barium or magnesium, metals of group IIb of the Periodic Table of the Elements (old IUPAC version), including the lanthanides and actinides, for example samarium. In addition, metals such as aluminum or indium, and combinations of all of the metals mentioned, may be used. In addition, lithium-containing organometallic compounds or LiF may be applied between the organic layer and the cathode in order to reduce the operating voltage.

The OLED of the present invention may additionally comprise further layers which are known to those skilled in the art. For example, a layer which eases the transport of the positive charge and/or matches the band gaps of the layers to one another may be applied between the layer (2) and the light-emitting layer (3). Alternatively, this further layer may serve as a protective layer. In an analogous manner, additional layers may be present between the light-emitting layer (3) and the layer (4) in order to ease the transport of the negative charge and/or to match the band gaps between the layers to one another. Alternatively, this layer may serve as a protective layer.

In a preferred embodiment, the inventive OLED, in addition to layers (1) to (5), comprises at least one of the further layers mentioned below:
a hole injection layer between the anode (1) and the hole-transporting layer (2);
a blocking layer for electrons between the hole-transporting layer (2) and the light-emitting layer (3);
a blocking layer for holes between the light-emitting layer (3) and the electron-transporting layer (4);
an electron injection layer between the electron-transporting layer (4) and the cathode (5).

However, it is also possible that the OLED does not have all of the layers (1) to (5) mentioned; for example, an OLED having the layers (1) (anode), (3) (light-emitting layer) and (5) (cathode) is likewise suitable, in which case the functions of the layers (2) (hole-transporting layer) and (4) (electron-transporting layer) are assumed by the adjacent layers. OLEDs which have the layers (1), (2), (3) and (5) or the layers (1), (3), (4) and (5) are likewise suitable.

Those skilled in the art know how suitable materials have to be selected (for example on the basis of electrochemical investigations). Suitable materials for the individual layers are known to those skilled in the art and disclosed, for example, in WO 00/70655.

Furthermore, each of the specified layers of the inventive OLED may be composed of two or more layers. In addition, it is possible that some or all of the layers (1), (2), (3), (4) and (5) have been surface-treated in order to increase the efficiency of charge carrier transport. The selection of the materials for each of the layers mentioned is preferably determined by obtaining an OLED having a high efficiency and lifespan.

The inventive OLED can be produced by methods known to those skilled in the art. In general, the inventive OLED is produced by successive vapor deposition of the individual layers onto a suitable substrate. Suitable substrates are, for example, glass or polymer films. For the vapor deposition, customary techniques may be used, such as thermal evaporation, chemical vapor deposition and others. In an alternative process, the organic layers may be coated from solutions or dispersions in suitable solvents, in which case coating techniques known to those skilled in the art are employed.

In general, the different layers have the following thicknesses: anode (1) from 500 to 5000 Å, preferably from 1000 to 2000 Å; hole-transporting layer (2) from 50 to 1000 Å, preferably from 200 to 800 Å; light-emitting layer (3) from 10 to 1000 Å, preferably from 100 to 800 Å; electron-transporting layer (4) from 50 to 1000 Å, preferably from 200 to 800 Å; cathode (5) from 200 to 10 000 Å, preferably from 300 to 5000 Å. The position of the recombination zone of holes and electrons in the inventive OLED and thus the emission spectrum of the OLED may be influenced by the relative thickness of each layer. This means that the thickness of the electron transport layer should preferably be selected such that the electron/hole recombination zone is within the light-emitting layer. The ratio of the layer thicknesses of the individual layers in the OLED is dependent upon the materials used. The layer thicknesses of any additional layers used are known to those skilled in the art.

Use of the phenothiazine S-oxide or phenothiazine S,S-dioxide derivatives of the formula I used in accordance with the invention as matrix materials in the light-emitting layer of the inventive OLEDs allows OLEDs having a high efficiency to be obtained. The efficiency of the inventive OLEDs may additionally be improved by optimizing the other layers. For example, highly efficient cathodes such as Ca or Ba, if appropriate in combination with an intermediate layer of LiF, may be used, Shaped substrates and novel hole-transporting materials which bring about a reduction in the operating voltage or an increase in the quantum efficiency are likewise usable in the inventive OLEDs. Furthermore, additional layers may be present in the OLEDs in order to adjust the energy level of the different layers and to ease electroluminescence.

The inventive OLEDs may be used in all devices in which electroluminescence is useful. Suitable devices are preferably selected from stationary and mobile visual display units. Stationary visual display units are, for example, visual display units of computers, televisions, visual display units in printers, kitchen appliances and advertising panels, illuminations and information panels. Mobile visual display units are, for example, visual display units in mobile telephones, laptops, digital cameras, vehicles and destination displays on buses and trains.

In addition, the phenothiazine S-oxide or phenothiazine S,S-dioxide derivatives of the formula I used in accordance with the invention may be used in OLEDs having inverse structure. In these inverse OLEDs, preference is given to using the compounds of the formula I used in accordance with the invention again as matrix materials in the light-emitting layer. The structure of inverse OLEDs and the materials customarily used therein are known to those skilled in the art.

The examples which follow additionally illustrate the invention.

### EXAMPLES

### Example 1

### 3-Phenylphenothiazine 5,5-dioxide

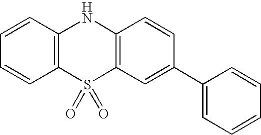

A suspension of 2.00 g (7.2 mmol) of 3-phenylphenothiazine (synthesized according to J. Cymerman-Craig, W. P. Rogers and G. P. Warwick, Aust. J. Chem. 1955, 8, 252-257) in 45 ml of methylene chloride was admixed at room temperature with stirring with 3.40 g (13.8 mmol) of 70% m-chloroperbenzoic acid in portions. After stirring at room temperature for 4 hours, the precipitate was filtered off, washed with methylene chloride and dried under reduced pressure. The crude product (0.95 g) was recrystallized twice from acetic acid. After the light gray solid had been dried at 100° C. under high vacuum, 0.492 g (22% of theory) of analytically pure substance having an m.p. of 269-272° C. was obtained, whose solution in tetrahydrofuran fluoresced at λ=383 nm.

### Example 2

### a) 10-Methyl-3,7-diphenylphenothiazine

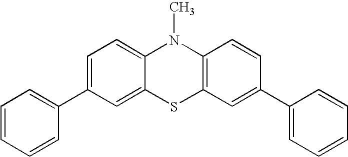

2.50 g (6.7 mmol) of 3,7-dibromo-10-methylphenothiazine (synthesized according to C. Bodea and M. Terdic, Acad. Rep. Rom. 1962, 13, 81-87), 1.85 g (14.9 mmol) of 98% phenyl boronic acid, 0.11 g (0.14 mmol) of bis(triphenylphosphine)palladium dichloride and 1.03 g (7.4 mmol) of potassium carbonate were heated to boiling (75° C.) under reflux under nitrogen for five hours in 55 ml of dimethoxyethane and 28 ml of water. The reaction mixture was cooled to room temperature and stirred further overnight. The precipitate was filtered off with suction, washed successively with 125 ml of ethanol and hot water and dried at 70° C. under reduced pressure. The crude product (2.30 g) was heated to boiling under reflux in cyclohexane for two hours. After the hot suspension had been filtered, the residue was dried, dissolved in 40 ml of methylene chloride and filtered through a silica gel-filled glass frit. After the solvent had been removed, 1.05 g (43% of theory) of light yellow, analytically pure solid having an m.p. of 239-241° C. were obtained, whose solution in chloroform fluoresced at λ=464 nm.

### b) 10-Methyl-3,7-diphenylphenothiazine 5,5-dioxide

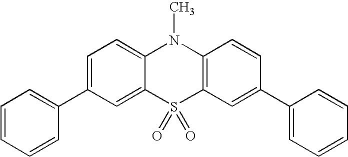

A solution of 1.95 g (5.3 mmol) of 10-methyl-3,7-diphenylphenothiazine in 65 ml of methylene chloride was admixed at room temperature with 2.67 g (10.7 mmol) of 70% m-chloroperbenzoic acid in portions and stirred at 20-25° C. for two hours. The reaction solution was subsequently extracted successively, twice in each case, with 10 ml of 10% potassium hydroxide solution, 10 ml of 5% hydrochloric acid and 10 ml of saturated sodium hydrogencarbonate solution. The organic phase was removed and purified by column chromatography (eluent: ethyl acetate). The resulting crude product (1.80 g) was recrystallized from toluene and subsequently sublimed under high vacuum. 0.65 g (31% of theory) of light beige, analytically pure solid having an m.p. of 242-245° C. was obtained, whose solution in chloroform fluoresced at λ=386 nm.

### Example 3

### a) 10-Methyl-3,7-bis(1-naphthyl)phenothiazine

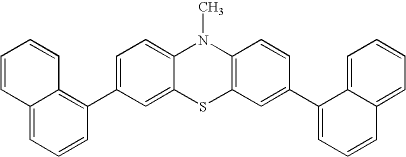

9.30 g (25.1 mmol) of 3,7-dibromo-10-methylphenothiazine, 9.50 g (55.2 mmol) of 1-naphthylboronic acid, 0.407 g (0.50 mmol) of bis(triphenylphosphane)palladium dichloride and 3.80 g (27.5 mmol) of potassium carbonate were heated to boiling under reflux under nitrogen for five hours in 204 ml of dimethoxyethane and 101 ml of water.

The reaction mixture was cooled to room temperature, stirred further overnight and then filtered. The residue was washed with 470 ml of ethanol and hot water, and dried at 70° C. under reduced pressure. The solid was dissolved in 100 ml of methylene chloride and filtered through silica gel. After the solvent had been removed under reduced pressure, a tacky mass was obtained which, after 200 ml of methanol had been added, crystallized with stirring overnight. The crystals were filtered off with suction, washed with 300 ml of methanol and dried at 40° C. under reduced pressure. 10.33 g of light yellow microcrystals having an m.p. of 185-190° C. were obtained. The crude product was recrystallized twice from ethyl acetate. 5.71 g (49% of theory) of analytically pure, almost colorless microcrystals having an m.p. of 191-194° C. were obtained, whose solution in chloroform fluoresced at λ=468 nm.

### b) 10-Methyl-3,7-bis(1-naphthyl)phenothiazine 5-oxide

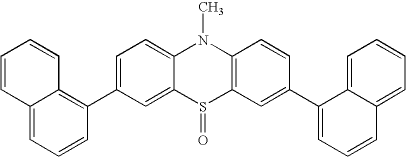

A solution of 1.20 g (5.35 mmol) of 77% m-chloroperbenzoic acid in 20 ml of methylene chloride was added dropwise to an ice-cooled suspension of 2.50 g (5.37 mmol) of 10-methyl-3,7-bis(1-naphthyl)phenothiazine in 60 ml of methylene chloride within 30 min. The reaction solution was stirred at 0-5° C. for 2 hours. Subsequently, a further 0.60 g (2.70 mmol) of m-chloroperbenzoic acid, dissolved in 10 ml of methylene chloride, was added dropwise. The solution was stirred at 0-5° C. for a further 2 hours and then warmed to room temperature. After the reaction solution had been extracted, in each case twice, with 15 ml of 10% KOH, 15 ml of 5% HCl and 25 ml of saturated sodium hydrogencarbonate solution, the organic phase was purified by column chromatography on silica gel (eluent: methylene chloride). The first fraction contained the sulfone (see Example 3c), of which 0.38 g (14% of theory) of analytically pure colorless solid having an m.p. of 221-225° C. was isolated, whose solution in chloroform fluoresced at λ=385 nm. After the sulfone had been removed, the eluent was switched to ethyl acetate, whereupon a second fraction was obtained. After the solvent had been removed, a tacky paste was obtained which crystallized after water had been added, 1.53 g (59% of theory) of analytically pure, light brown solid having a decomposition point of >1650 were obtained, whose solution in chloroform fluoresced at λ=388 nm.

### c) 10-Methyl-3,7-bis(1-naphthyl)phenothiazine 5,5-dioxide

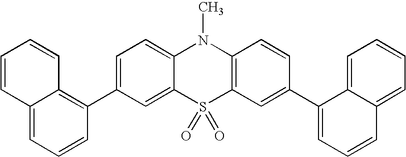

For the preparation as a by-product in the synthesis of 10-methyl-3,7-bis(3-naphthyl)-phenothiazine 5-oxide, see under b). For a selective preparation of the sulfone, it is advisable to use at least two molar equivalents of m-chloroperbenzoic acid. Colorless microcrystals having an m.p. of 221-225° C. were obtained, whose solution in chloroform fluoresced at λ=385 nm.

### Example 4

### a) 10-Methyl-3,7-bis(2-naphthyl)phenothiazine

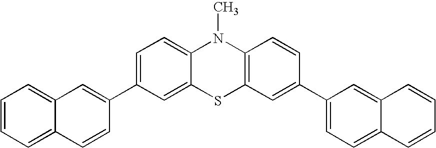

9.30 g (25.1 mmol) of 3,7-dibromo-10-methylphenothiazine, 9.50 g (55.2 mmol) of 2-naphthylboronic acid, 0.407 g (0.50 mmol) of bis(triphenylphosphine)palladium dichloride and 3.80 g (27.5 mmol) of potassium carbonate were heated to boiling under reflux under nitrogen for five hours in 204 ml of dimethoxyethane and 101 ml of water. The reaction mixture was cooled to room temperature, stirred further overnight and then filtered. The residue was washed with 470 ml of ethanol and hot water, and then dried at 70° C. under reduced pressure. The solid was dissolved in 200 ml of methylene chloride and filtered through silica gel. After the solvent had been removed under reduced pressure, 9.6 g of greenish-yellow solid were obtained (m.p. 276-281° C.) and were recrystallized from 500 ml of toluene. 7.10 g (61% of theory) of analytically pure, shiny yellow microcrystals having an m.p. of 285-289° C. were obtained, whose solution in chloroform fluoresced at λ=402 nm.

### b) 10-Methyl-3,7-bis(2-naphthyl)phenothiazine 5-oxide

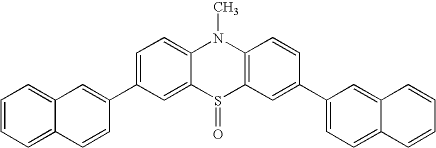

A solution of 1.20 g (5.35 mmol) of 77% m-chloroperbenzoic acid in 20 ml of methylene chloride was added dropwise to an ice-cooled suspension of 2.50 g (5.37 mmol) of 10-methyl-3,7-bis(2-naphthyl)phenothiazine in 60 ml of methylene chloride within 30 min. The reaction solution was stirred at 0-5° C. for 2 hours. Subsequently, a further 0.60 g (2.70 mmol) of m-chloroperbenzoic acid, dissolved in 10 ml of methylene chloride, was added dropwise. The solution was stirred further at 0-5° C. for 2 hours and then warmed to room temperature. After the reaction mixture had been extracted, in each case twice, with 15 ml of 10% KOH, 15 m of 5% HC and 25 ml of saturated sodium hydrogencarbonate solution, the organic phase was purified by column chromatography on silica gel (eluent: methylene chloride). The first fraction contained 0.62 g of sulfone (see under c)), which was recrystallized from 36 ml of o-dichlorobenzene. 0.44 g (16% of theory) of yellowish solid having an m.p. of 328-332° C. was obtained. After the sulfone had been removed, the eluent was switched to ethyl acetate. After the solvent had been removed, 1.30 g of solid were obtained and were recrystallized from 134 ml of acetic acid. 0.54 g (21% of theory) of analytically pure, beige solid having an m.p. of 275-280° C. were obtained, whose solution in chloroform fluoresced at λ=402 nm.

### c) 10-Methyl-3,7-bis(2-naphthyl)phenothiazine 5,5-dioxide

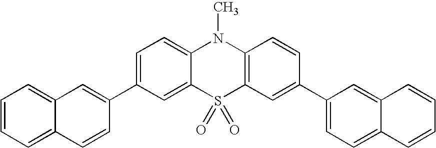

For the preparation as a by-product in the synthesis of 10-methyl-3,7-bis(2-naphthyl)-phenothiazine 5-oxide, see under b). For a selective preparation of the sulfone, it is advisable to use at least two molar equivalents of m-chloroperbenzoic acid. Yellowish microcrystals having an m.p. of 328-332° C. were obtained.

### Example 5

### a) 1,3-Phenylene-10,10-bis(phenothiazine)

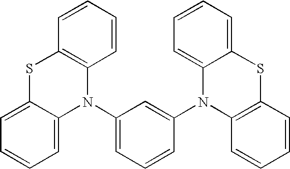

The preparation was effected according to K Okada et al. J. Am. Chem. Soc. 1996, 118, 3047-3048.

18.5 g (91.9 mmol) of phenothiazine, 15.6 g (46.3 mmol) of 98% 1,3-diiodobenzene 19.4 g (140 mmol) of potassium carbonate and 1.16 g (18.3 mmol) of activated copper powder were heated to 200° C. and stirred at this temperature for 24 h. The reaction mixture was cooled to 140° C. and with then admixed with 200 ml of ethyl acetate. The suspension was heated to boiling under reflux for one hour and subsequently hot-filtered. The filtrate was diluted with 300 ml of methanol and a solid precipitated out and was filtered off with suction, washed with methanol and dried at 80° C. under reduced pressure, 8.91 g of pink solid having an p, of 186-185 were obtained.

### b) 1,3-Phenylene-10,10′-bis(phenothiazine) 5,5′-dioxide

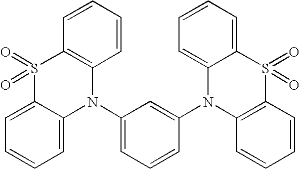

6.28 g (13.3 mmol) of 1,3-phenylene-10,10′-bis(phenothiazine) were dissolved in 220 ml of methylene chloride. After stirring at room temperature for 15 min, 17.9 g (79.9 mmol) of 77% m-chloroperbenzoic acid were added in portions. The reaction solution was stirred at room temperature for 24 h, in the course of which a solid precipitated out. The solution was filtered, and the residue was washed with methylene chloride and suction-dried. The solid was suspended in hot water. The aqueous suspension was adjusted to pH 11 with 5% potassium hydroxide solution and subsequently hot-filtered. The residue was washed with hot water and dried at 80° C. under reduced pressure. The solid (5.07 g) was recrystallized from dimethylformamide. 3.72 g of colorless microcrystals having an m.p. of 412° C. were obtained in analytically pure form, whose solution in toluene fluoresced at λ=375 nm (S).

### Example 6

### a) 1,4-Phenylene-10,10′-bis(phenothiazine)

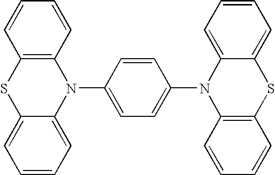

The preparation was effected according to K. Okada et al., J. Am. Chem. Soc. 1996, 118, 3047-3048.

19.9 g (98.9 mmol) of phenothiazine, 16.6 g (49.8 mmol) of 99% 1,4-diiodobenzene, 20.9 g (151 mmol) of potassium carbonate and 1.25 g (19.7 mmol) of activated copper powder were heated to 196° C. and stirred at this temperature for 17 h. After the reaction mixture had been cooled to room temperature, 200 ml of hot water were added. The suspension was stirred for one hour and subsequently filtered. The residue was washed with hot water and dried at 80° C. under reduced pressure. The crude product (21.6 g) was heated to boiling under reflux in 200 ml of methylene chloride for one hour. After the solution had been cooled to room temperature, it was filtered through silica gel. Three fractions were obtained of which the first two were combined (11.7 g) and were recrystallized from ethyl acetate. The third fraction contained the desired product of value (5.0 g). In total, 13.47 g of beige solid having an m.p. of 254-263° C. were obtained.

### b) 1,4-Phenylene-10,10′-bis(phenothiazine) 5,5′-dioxide

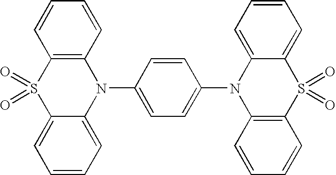

4.98 g (10.5 mmol) of 1,4-phenylene-10,10-bis(phenothiazine) were dissolved in 175 ml of methylene chloride. After stirring at room temperature for 1 h, 10.41 g (46.5 mmol) of 77% m-chloroperbenzoic acid were added in portions. The reaction solution was stirred at room temperature for 24 h, in the course of which the solid precipitated out. The solution was filtered, and the residue was washed with methylene chloride and suction-dried. The solid was suspended in 200 ml of hot water. The aqueous suspension was adjusted to pH 11.3 with 5 ml of 10% potassium hydroxide solution, stirred for 1 h and subsequently hot-filtered. The residue was washed with hot water and dried at 80° C. under reduced pressure. The solid (5.37 g) was recrystallized twice from sulfolane. 2.87 g (51%) of pale pink microcrystals having an m.p. of >360° C. were obtained in analytically pure form whose solution in methylene chloride fluoresced at λ=480 nm.

### Example 7

### 10-Methylphenothiazine 5,5-dioxide

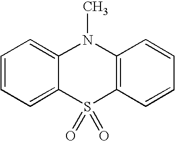

The preparation was effected according to M. Tosa et al., Heterocyclic Commun. 7 (2001) 277-282.

A solution of 10.0 g (45.9 mmol) of 98% 10-methylphenothiazine in 350 ml of methylene chloride was admixed at room temperature with 22.65 g (91.9 mmol) of 70% m-chloroperbenzoic acid and stirred at 20-25° C. for 5 h. After the solution had been filtered, the filtrate was extracted successively twice with in each case 100 ml of 10% potassium hydroxide solution, 100 ml of 5% hydrochloric acid and 70 ml of saturated sodium hydrogencarbonate. The organic phase was concentrated to 150 ml and then filtered through silica gel. From the second fraction 4.89 g (43% of theory) of beige microcrystals having an m.p. of 226-235° C. (lit. 225-226° C.) were isolated in analytically pure form. Recrystallization in acetic acid afforded colorless crystals which melted at 226-233° C. A solution of the substance in chloroform fluoresced at λ=351, 376 (S) nm.

### Example 8

### a) 10-Phenylphenothiazine

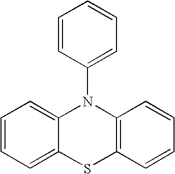

The preparation was effected according to D. Li et al., Dyes and Pigments 49 (2001) 181-186.

96.0 g (482 mmol) of phenothiazine, 298.5 g (1434 mmol) of 98% iodobenzene, 80.0 g (579 mmol) of potassium carbonate and 2.00 g (31.5 mmol) of copper powder were heated to 190-200° C. and stirred at this temperature for 6 h. Subsequently, the excess iodobenzene was distilled off. The reaction mixture was diluted with 480 ml of ethanol and heated to boiling under reflux for 1 h. The solution was hot-filtered. After cooling, the precipitate was filtered off with suction, washed with ethanol and dried under reduced pressure. 77.7 g (58.5% of theory) of gray microcrystals having an m.p. of 95-96° C. (lit, 95-97° C.) were obtained.

### b) 0-Phenylphenothiazine 5,5-dioxide

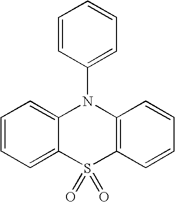

The compound known from the literature H. Gilman and R. O. Ranck, J. Org, Chem. 1958, 23, 1903-1906) was prepared in analogy to M. Tosa et al., Heterocyclic Commun. 7 (2001) 277-282.

A solution of 5.50 g (20.0 mmol) of 10-phenylphenothiazine in 220 ml of methylene chloride was admixed at room temperature with 11.84 g (48.0 mmol) of 70% m-chloroperbenzoic acid and stirred at 20-25° C. for 8 h. The solution was concentrated to dryness. The residue was suspended in hot water and heated to 80-85° C. At this temperature, the pH was adjusted to 7-8 with 32 ml of 100% potassium hydroxide solution. The solution was stirred for a further 30 min, then filtered, washed with hot water and dried at 80° C. under reduced pressure. The crude product (5.77 g) was dissolved in 30 ml of methylene chloride and filtered through silica gel. From the second fraction, 2.92 g (47% of theory) of beige microcrystals having an m.p. of 212-217° C. (lit. 212-213° C.) were isolated in analytically pure form Recrystallization in acetic acid afforded colorless crystals which melted at 212-217° C. A solution of the substance in chloroform fluoresced at λ=348, 386 (S), 452 (S) nm.

### Example 9

### a) 0-(4-Methoxyphenyl phenothiazine

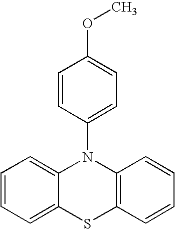

8.77 g (94.2 mmol) of phenothiazine, 66.5 g (284 mmol) of 98% 4-iodoanisole, 15.7 g (114 mmol) of potassium carbonate and 0.392 (6.17 mmol) of copper powder were heated to 190-200° C. and stirred at this temperature for 48 h. Subsequently the excess iodobenzene was distilled off. The reaction mixture was admixed with 200 ml of hot water and heated at 90° C. for 1 h. The solution was hot-filtered. After cooling, the precipitate was filtered off with suction washed with ethanol and dried under reduced pressure. The crude product (29.0 g) was recrystallized from 345 ml of acetic acid. 22.54 g (78.4% of theory) of beige microcrystals having an m.p. of 173-176° C. (lit. 172-174° C.) were obtained.

### b) 0-(4-Methoxyphenyl)phenothiazine 5,5-dioxide

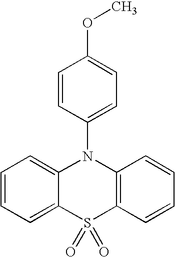

A solution of 5.00 g (16.4 mmol) of 10-(methoxyphenyl)phenothiazine in 175 ml of methylene chloride was admixed at room temperature with 9.76 g (39.6 mmol) of 70% m-chloroperbenzoic acid and stirred at 20-25° C. for 4 h. The solution was concentrated to dryness. The residue was taken up with 200 ml of hot water and heated to 80-85° G. At this temperature, the pH was adjusted to 7-8 with 25 ml of 10% potassium hydroxide solution. The solution was stirred for a further 30 min, then filtered washed with hot water and dried at 80° C. under reduced pressure. The crude product (5.25 g) was dissolved in 70 ml of methylene chloride and filtered through silica gel. After the solvent had been removed, 4.41 g (80% of theory) of colorless microcrystals having an m.p. of 265-266° G were isolated in analytically pure form. Recrystallization in acetic acid afforded colorless crystals which melted at 264-270° C. A solution of the substance in chloroform fluoresced at λ=474 nm.

### Example 10

### a) 0-Mesitylphenothiazine

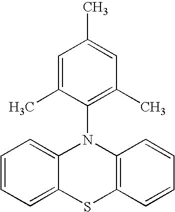

9.92 g (49.8 mmol) of phenothiazine, 25.0 g (99.6 mmol) of 98% 2,4,6-trimethyliodo-benzene, 8.30 g (600 mmol) of potassium carbonate and 0.207 g (3.26 mmol) of copper powder were heated to 180° and stirred at this temperature for 24 h.

Subsequently, the excess 2,4,6-trimethyliodobenzene was distilled off. The reaction mixture was admixed with 300 ml of water and stirred overnight. The suspension was filtered, washed to neutrality with hot water and dried at 80° C. under reduced pressure. The crude product (16.6 g) was heated in 500 ml of ethanol to boiling under reflux for 2 h and then diluted with 200 ml of water. The precipitate was filtered off with suction, dried at 80° C. under reduced pressure (10.5 g) and dissolved in 150 ml of toluene. The solution was filtered through silica gel. After the filtrate had been concentrated, 7.22 g of light brown microcrystals having an m.p. of 192-200° C. were obtained.

### b) 0-Mesitylphenothiazine 5,5-dioxide

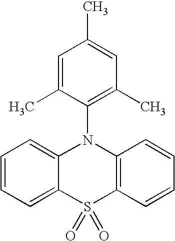

A solution of 1.50 g (4.73 mmol) of 10-mesitylphenothiazine in 55 ml of methylene chloride was admixed at room temperature with 2.80 g (11.4 mmol) of 70% m-chloro-perbenzoic acid and stirred at 20-25° C. for 8 h. The solution was extracted successively twice with in each case 20 ml of 10% potassium hydroxide solution, 20 ml of 5% hydrochloric acid and 15 ml of saturated sodium hydrogencarbonate solution. The solution was filtered through silica gel. After the filtrate had been concentrated, 1.43 g (86% of theory) of beige microcrystals having an m.p. of 242-246° C. were isolated in analytically pure form. Recrystallization in acetic acid afforded colorless crystals which melted at 240-246° C. A solution of the substance in chloroform fluoresced at λ=349, 370 (S) nm.

### Example 11

### a) 1,35-Phenylene-10,10′, 10″-tris(phenothiazine)

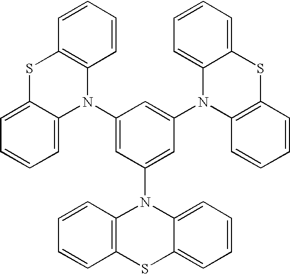

30.19 g (150 mmol) of phenothiazine were added at room temperature to a suspension of 6.00 g (150 mmol) of sodium hydride (60% dispersion in paraffin oil) in 150 ml of anhydrous dimethylformamide with stirring and under nitrogen, in the course of which the reaction temperature rose to 40° C. When the evolution of hydrogen had ended (approx. 20 min), a solution of 6.20 g (46.0 mmol) of 98% 1,3,5-trifluorobenzene in 10 ml of dimethylformamide was added dropwise to the reaction solution within 15 min Subsequently, the reaction solution was heated initially at 80° C. for two hours, then at 100° C. for 16 hours. After cooling to room temperature, the reaction solution was precipitated in 500 ml of ice-water. The precipitate was filtered off with suction, washed to neutrality with hot water and then dispersed in 500 ml of methanol. The suspension was heated to boiling under reflux for one hour. After cooling to room temperature, the solid was filtered off with suction, washed with methanol and dried at 50° C. under reduced pressure. 24.80 g of solid were obtained and were heated in ethyl acetate to boiling under reflux for one hour. After cooling to room temperature, the solid was filtered off with suction, washed with ethyl acetate and heated in ethyl acetate once more to boiling under reflux for one hour. After cooling to room temperature, the solid was filtered off with suction, washed with ethyl acetate and dried at 80° C. under reduced pressure. 23.34 g (76% of theory) of light gray solid having a melting point of 264-268 were obtained.

### b) 1,3,5-Phenylene-10,10′,10″-tris(phenothiazine 5,5-dioxide)

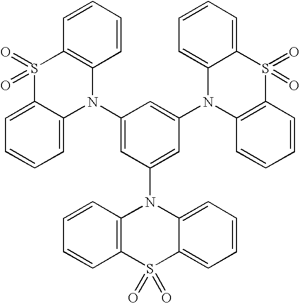

A solution of 6.709 g (10.0 mmol) of 1,3,5-phenylene-10,10′,10″-tris(phenothiazine) in 180 ml of methylene chloride was admixed at room temperature with 22.19 g (90.0 mmol) of 70% m-chloroperbenzoic acid in portions and stirred at 20-25° C. for 24 h. The reaction mixture was concentrated to dryness, then admixed with 150 ml of hot water and 46 ml of 10% potassium hydroxide solution. The solid was filtered off with suction, washed to neutrality with hot water and dried at 80° C. under reduced pressure. 7.63 g of beige microcrystals having a melting point of >360° C. were obtained.

### Example 12

### 4-(5,5-Dioxophenothiazin-10-yl)phenyl benzoate

### a) 10-(2-Hydroxyphenyl)phenothiazine

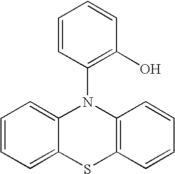

35.9 g (180 mmol) of phenothiazine, 44.59 (198 mmol) of 98% 4-iodophenol (2-iodophenol may likewise be used), 29.9 g (216 mmol) of potassium carbonate and 0.75 g (12 mmol) of copper powder were heated to 198° C. and stirred at this temperature for 3.5 h. The reaction melt was cooled to 140° C. and then admixed with 150 ml of water within 3 min which solidified the reaction mixture. After cooling with dry ice, the solid was isolated, comminuted in a mortar and pestle and admixed with 150 ml of water. The suspension was subjected to a steam distillation in order to remove excess iodophenol. Subsequently, the solid was filtered off with suction and washed with water. The water-moist solid was suspended in 400 ml of ethanol, stirred at room temperature overnight, then filtered off with suction, washed with ethanol and dried at 80° C. under reduced pressure. The crude product (16.6 g) was heated to boiling under reflux in 500 ml of ethanol for 2 h and then diluted with 200 ml of water. The precipitate was filtered off with suction, dried at 80° C. under reduced pressure (10.5 g) and dissolved in 150 ml of toluene. The solution was filtered through silica gel. After the filtrate had been concentrated, 7.22 g of light brown microcrystals having a melting point of 192-200° C. were obtained.

### b) 2-(Phenothiazin-10-yl)phenyl benzoate

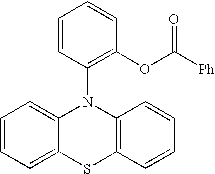

16.0 g (114 mmol) of benzoyl chloride were added dropwise at 0-5° C. with stirring to a solution of 4.00 g (13.7 mmol) of 10-(2-hydroxyphenyl)phenothiazine in 24 ml of pyridine within 30 min. After stirring at room temperature for 2 h, the reaction solution was heated to 60-65° C. and stirred at this temperature for 15 min. After cooling to room temperature, the suspension was stirred overnight. After adding 300 ml of ice-water the suspension was admixed slowly with 19 ml of conc. hydrochloric acid (pH 0.9) and stirred for 1 h. The suspension was filtered through a glass frit. The residue was washed to neutrality with 2 l of water and dried at 60° C. under reduced pressure. 2.87 g (53% of theory) of colorless microcrystals having a melting point of 144-148° C. were obtained.

### c) 2-(5,5-Dioxophenothiazin-10-yl)phenyl benzoate

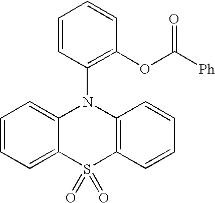

A solution of 1.32 g (3.33 mmol) of 2-(phenothiazin-10-yl)phenyl benzoate in 50 ml of methylene chloride was admixed at room temperature with 1.81 g (7.33 mmol) of 70% m-chloroperbenzoic acid and stirred at 20° C. for 24 h. The solution was concentrated to dryness under reduced pressure. The residue was taken up in 50 ml of water. The suspension was heated to 80° C. and, after adding 4.5 ml of 10% potassium hydroxide solution, stirred for 20 min. The beige solid was filtered off with suction while hot, washed with hot water and dried at 70° C. (1.285 g). A solution of the solid in 22 ml of methylene chloride was filtered through MN 60 silica gel which was subsequently washed with a mixture of 100 parts of methylene chloride and 1 part of methanol. After the filtrate had been concentrated, the residue was recrystallized from acetic acid. 0.93 g (65% of theory) of colorless microcrystals were obtained which melted at 228-232° C.

### Example 13

### 10-(2-Hydroxyphenyl)phenothiazine 5,5-dioxide

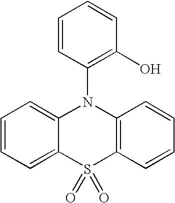

A solution of 1.50 g (5.14 mmol) of 10-(2-hydroxyphenyl)phenothiazine in 50 ml of methylene chloride was admixed at room temperature with 2.79 g (11.31 mmol) of 70% m-chloroperbenzoic acid, and stirred at room temperature for 5.5 h. The solution was concentrated to dryness under reduced pressure. The residue was taken up in 100 ml of water. The suspension was heated to 80° C. and, after adding 7.5 ml of 10% potassium hydroxide solution, stirred for 20 min. The solid was filtered off with suction while hot, washed with hot water and dried at 70° C. (1.45 g). The beige solid was recrystallized twice from 42 ml of acetic acid each time. 0.92 g (55% of theory) of colorless microcrystals were obtained which melted at 282-287° C.

### Example 14

### 4-(5,5-Dioxophenothiazin-10-yl)phenyl benzoate

### a) 4-Iodophenyl benzyl ether

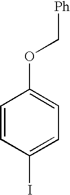

A reaction mixture of 21.40 g (95.3 mmol) of 98% 4-iodophenol, 12.19 g (95.3 mmol) of 99% benzyl chloride, 20.73 g (150 mmol) of potassium carbonate and 250 ml of acetone were heated to reflux temperature and heated to boiling for 30 hours. After cooling to room temperature, the reaction mixture was filtered. The filtrate was concentrated and then cooled in an ice bath, and a solid precipitated out. This was removed by means of a blue-band filter and then dried. The crude product (23.22 g) was recrystallized from 70 ml of ethanol. 17.20 g (58% of theory) of colorless microcrystals having an m.p. of 61-62° C. (lit. 62° C.) were obtained.

### b) 10-(4-Benzyloxyphenyl)phenothiazine

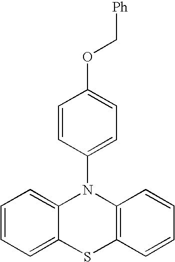

5.56 g (27.9 mmol) of phenothiazine, 8.65 g (27.9 mmol) of 4-iodophenyl benzyl ether, 4.64 g (33.5 mmol) of potassium carbonate and 0.116 g (1.82 mmol) of copper powder were heated to 190° C. and stirred at this temperature for 24 h. The reaction melt was cooled to 110° C., then diluted with 200 ml of toluene and stirred at 112° C. for one hour. The solution was hot-filtered. The filtrate was cooled to room temperature and then purified on silica gel in toluene. The beige crude product (6.52 g) was recrystallized from 125 ml of ethanol 4.79 g (45% of theory) of beige microcrystals having an m.p. of 144-146° C. were obtained.

### c) 10-(4-Benzyloxyphenyl)phenothiazine 5,5-dioxide

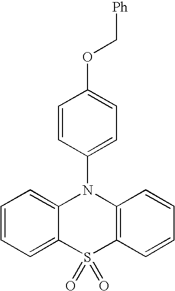

A solution of 4.60 g (12.1 mmol) of 10-(4-benzyloxyphenyl)phenothiazine in 130 ml of methylene chloride was admixed at room temperature with 6.53 g (26.5 mmol) of 70% m-chloroperbenzoic acid and stirred at room temperature for 3 h. The solution was concentrated to dryness under reduced pressure. The residue was taken up in 150 ml of water. The suspension was heated to 80° C. and, after adding 14 ml of 10% potassium hydroxide solution, stirred for 20 min. The solid was filtered off with suction while hot, washed with hot water and dried at 100° C. 4.78 g (96% of theory) of beige solid with an m.p. of 203-208° C. were obtained. in order to remove methylene chloride residues, 0.96 g of solid was sublimed at 200° C. under high vacuum. 0.78 g of analytically pure colorless microcrystals were obtained, which melted at 204-208° C.,

### d) 10-(4-Hydroxyphenyl)phenothiazine 5,5-dioxide

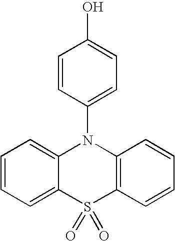

3.10 g 7.50 mmol) of 10-(4-benzyloxyphenyl)phenothiazine 5,5-dioxide, 2.30 g (35.7 mmol) of 98% ammonium formate and 7.5 g of 10% palladium on activated carbon were heated to boiling under reflux in 225 ml of acetone for one hour. After cooling to room temperature, the solution was filtered. The filtrate was concentrated and, after adding 10 ml of methanol, stirred overnight. The solid was filtered off with suction, washed with methanol and dried at 110° C. in a vacuum drying cabinet, 1.47 g (61% of theory) of analytically pure light gray microcrystals having an m.p. of 308-311° C. were obtained.

### e) 4-(5,5-Dioxophenothiazin-10-yl)phenyl benzoate

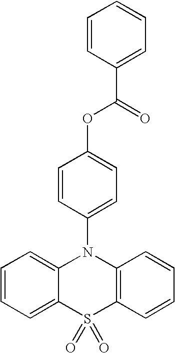

0.68 g (6.68 mmol) of triethylamine and 0.34 g (2.44 mmol) of benzoyl chloride were added to a solution of 0.72 g (2.22 mmol) of 10-(4-hydroxyphenyl)phenothiazine 5,5-dioxide in 120-ml of acetonitrile. After stirring at room temperature for 45 min, the solvent was distilled off. The residue was taken up in 100 ml of hot water and stirred at 75° C. for 30 min. The solid was filtered off with suction while hot, washed with hot water and dried at 120° C. in a forced-air drying cabinet. 0.87 g (92% of theory) of colorless microcrystals having an m.p. of 233-235° C. were obtained.

### Example 15

### 10-(3,5-Difluorophenyl)phenothiazine 5,5-dioxide

### a) 10-(3,5-Difluorophenyl)phenothiazine

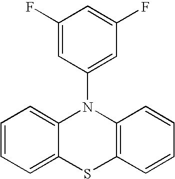

10.07 g (50.0 mmol of phenothiazine were added at room temperature, with stirring and under nitrogen to a suspension of 2.00 g (50.0 mmol) of sodium hydride (60% dispersion in paraffin oil) in 100 ml of anhydrous dimethylformamide within 10 min, in the course of which the reaction temperature rose to 32° C. Once the evolution of hydrogen had ended (approx. 20 min), a solution of 7.41 g (55.0 mol) of 98% 1,3,5-trifluorobenzene in 50 ml of dimethylformamide were added dropwise into the reaction solution heated to 85° C. within 15 min. Subsequently, the reaction solution was stirred at this temperature for 24 hours. After cooling to room temperature, the reaction solution was precipitated slowly in 500 ml of ice-water. After adding 18 g of sodium chloride, the aqueous suspension was stirred for 2 h and then filtered. The residue was washed with water and dried. The solid was suspended in 200 ml of hexane and heated under reflux for 1 h. After cooling to room temperature, the suspension was filtered. The filtrate was concentrated to dry ness under reduced pressure. The residue (7.00 g) was stirred in 230 ml of a mixture of 40 parts of hexane and 1 part of ethyl acetate, and filtered. The filtrate was chromatographed on silica gel with an eluent composed of 40 parts of hexane and 1 part of ethyl acetate. After the solvent had been removed, the residue was dried at 80° C. and 1.8×10⁻⁵ bar, in the course of which some of the substance sublimed. The solid remaining in the original vessel was recrystallized from 40 ml of ethanol, 1.18 g (7.6% of theory) of analytically pure colorless microcrystals having a melting point of 111-115° C. were obtained.

### b) 10-(3,5-Difluorophenyl)phenothiazine 5,5-dioxide

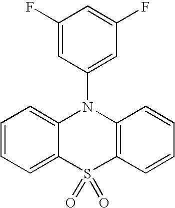

A solution of 1.40 g (4.50 mmol) of 10-(3,5-difluorophenyl)phenothiazine in 40 ml of methylene chloride was admixed at room temperature with 2.46 g (1 mmol) of 70% m-chloroperbenzoic acid, and stirred at room temperature for 2 h. The solution was concentrated to dryness under reduced pressure. The residue was stirred in 100 ml of water at 50° C. for 30 min. The suspension was admixed with 7.5 ml of 10% potassium hydroxide solution, stirred for 30 min and then filtered. The solid was filtered off with suction while hot, washed with hot water and dried at 80° C. The beige solid (1.54 g) was recrystallized twice from acetic acid. After drying at 130° C. under high vacuum, 0.73 g (47% of theory of analytically pure colorless microcrystals were obtained, which melted at 255-258° C.

### Example 16

### 10-(2-Pyridyl)phenothiazine 5,5-dioxide

### a) 10-(2-Pyridyl)phenothiazine

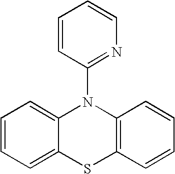

4.46 g (22.4 mmol) of phenothiazine, 9.36 g (47.6 mmol) of 98% 2-iodopyridine, 3.72 g (26.9 mmol) of potassium carbonate and 0.093 g (1.5 mmol) of copper powder were heated to 192° C. and stirred at this temperature for 24 h. The reaction melt was cooled to 100° C., then diluted slowly with 200 ml of ethanol and heated to boiling under reflux for one hour. After cooling to room temperature, the reaction mixture was filtered, which left a tacky paste which was dissolved in 100 ml of methylene chloride. The methylene chloride solution was purified on silica gel to obtain to fractions. The second fraction was concentrated to dryness. 2.55 g (41% of theory) of beige microcrystals having a melting point of 107-109° C. (lit.: 109-110° C.) were obtained.

### b) 10-(2-Pyridyl)phenothiazine 5,5-dioxide

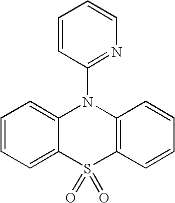

A solution of 2.20 g (7.96 mmol) of 10-(2-pyridyl)phenothiazine in 80 ml of methylene chloride was admixed at room temperature with 4.32 g (17.5 mmol) of 70% m-chloroperbenzoic acid with cooling, and stirred at room temperature for 2 h. The solution was concentrated to dryness under reduced pressure. The residue was taken up in 200 ml of water at 70° C. and admixed with 10 ml of 10% KOH. After stirring for 30 min, the suspension was filtered. The residue was washed with hot water and dried at 50° C. under reduced pressure. The colorless solid (1.87 g) was dissolved in 20 ml of a mixture of 99 parts of methylene chloride and one part of methanol, and purified on silica gel. The purified solution was concentrated to dryness. After the residue had been dried at 70° C. under reduced pressure, it was recrystallized from 10 ml of acetic acid. 1.09 g (44% of theory) of analytically pure colorless microcrystals were obtained, which melted at 186-190° C. After prolonged standing of the filtrate in acetic acid at room temperature, another 0.32 g of colorless microcrystals having a melting point of 184-188° C. precipitated out (total yield: 57%).

### Example 17

### 10-[4-(N-Phenyl-2-benzimidazolyl)phenyl]phenothiazine 5,5-dioxide

### a) N-Phenyl-2-(4-iodophenyl)benzimidazole

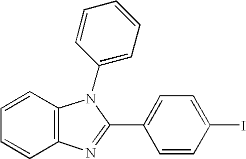

37.47 g (136 mmol) of 97% 4-iodobenzoyl chloride and 12.82 g (68.2 mol) of 98% o-aminodiphenylamine were heated to 100° C., and a stirrable melt formed from 85-90° C. Once the evolution of gas had ended (5 min), the melt solidified. The reaction mixture was kept at 100° C. for another 3 hours. After cooling, it was admixed with 100 ml of ethanol with stirring. The precipitate was filtered off with suction, washed with ethanol and stirred again in 400 ml of ethanol. The suspension was heated to 75° C., which formed a solution which was adjusted to pH 8 with 29 ml of 25% ammonia. After cooling to 5-10° C., the precipitate was filtered off with suction, washed with cold ethanol and dried at 75° C. in a vacuum drying cabinet. 18.37 g (68% of theory of light gray microcrystals having a melting point of 178-181° C. were obtained.

### b) 10-[4-(N-Phenyl-2-benzimidazolyl phenyl]phenothiazine

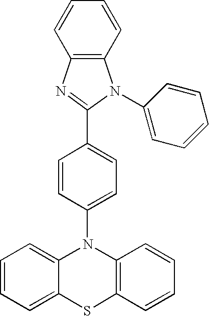

7.77 g (39.0 mmol) of phenothiazine, 17.00 g (42.9 mmol) of N-phenyl-2-(4-iodo-phenyl)benzimidazole, 6.47 g 46.8 mmol) of potassium carbonate and 0.162 g (2.54 mmol) of copper powder were heated to 195-200° C. and stirred at this temperature for 19 h. The reaction melt was cooled to 130° C. and then diluted with 100 ml of ethanol. After heating under reflux for 30 min, the solution was hot-filtered. The suspension was concentrated to dryness and then admixed with 150 ml of methylene chloride. After filtration, the filtrate was filtered through silica gel. 11.03 g of beige microcrystals were obtained.

### c) 10-[4-(N-Phenyl-2-benzimidazolyl)phenyl]phenothiazine 5,5-dioxide

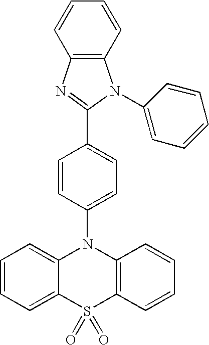

A solution of 6.14 g of 10-[4-(N-phenyl-2-benzimidazolyl)phenyl]phenothiazine in 180 ml of methylene chloride was admixed at room temperature with 7.17 g (28.9 mmol) of 70% m-chloroperbenzoic acid with cooling, and stirred at room temperature for 1 h. The solution was admixed with 60 ml of 10% KOH. After the methylene chloride had been removed, the suspension was diluted with 100 ml of hot water. The precipitate was filtered off with suction, washed with hot water and dried at 80° C. under reduced pressure. The crude product (4.82 g) was recrystallized from 48 ml of acetic acid. 3.02 g (46% of theory) of beige microcrystals having an m.p. of 286-288° C. were obtained.

### Example 18

### Production of an OLED

The ITO substrate used as the anode is first cleaned with commercial detergents for LCD production (Deconex® 20NS and 250RGAN-ACID® neutralizing agent) and subsequently in an acetone/isopropanol mixture in an ultrasound bath. To remove possible organic residues, the substrate is exposed to a continuous ozone flow in an ozone oven for a further 25 minutes. This treatment also improves the hole injection of the ITO.

Afterward, the organic materials specified below are applied by vapor deposition to the clean substrate at about 10⁻⁷ mbar at a rate of approx. 2 nm/min. As a hole conductor, 1-TNATA (4,4′,4″-tris(N-(naphth-1-yl)-N-phenylamino)triphenylamine) is first applied to the substrate in a layer thickness of 17.5 nm. This is followed by the deposition of a 9.5 nm-thick exciton blocker layer of the compound 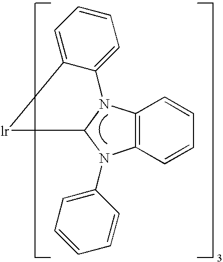
(for the preparation, see Ir complex (7) in the application PCT/EP/04/09269)

Subsequently, a mixture of 34% by weight of the compound 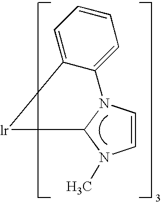
and 66% by weight of the compound 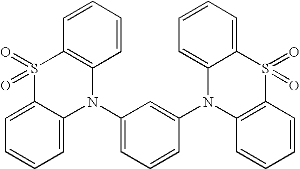
(see Example 5b)) are applied by vapor deposition in a thickness of 20 nm, the former compound serving as the emitter, the latter as the matrix material. Afterward, a BCP hole blocker and electron conductor layer is applied by vapor deposition in a thickness of 47.5 nm, then a 0.75 nm-thick lithium fluoride layer and finally a 110 nm-thick Al electrode.

To characterize the OLEDs, electroluminescence spectra are recorded at various currents and voltages. In addition, the characteristic current-voltage line is measured in combination with the emitted light output. The light output may be converted to photometric quantities by calibration with a luminance meter.

For the above-described OLED, the following electrooptical data are obtained:

| Emission maximum | 486 | nm |
|---|---|---|
| CIE(x, y) | 0,17; 0,21 | |
| Photometric efficiency | 11.7 | cd/A |
| Output efficiency | 9.9 | lm/W |
| External quantum yield | 7.3% | |
| Photometric efficiency at an | 10.3 | cd/A |
| illumination density of 100 cd/m² | | |
| Maximum illumination density | 2700 | cd/m² |

1-8. (canceled)

9. A method of using as a matrix material in organic light-emitting diodes a compound of formula I 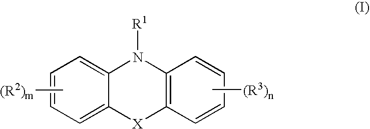
wherein:
X is an SO or SO₂ group,
R¹ is hydrogen, alkyl, cyclic alkyl, heterocyclic alkyl, aryl, heteroaryl, a moiety of formula II 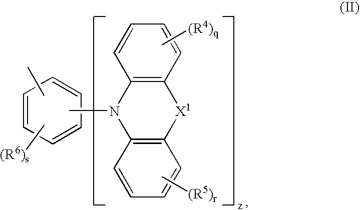
a moiety of formula III 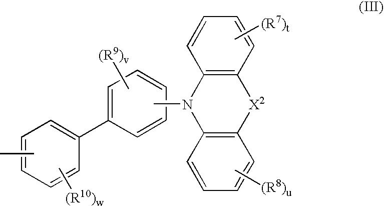
or
a moiety of formula IV 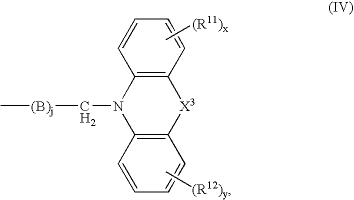
X¹, X², X³ are each independently, and independently of X, an S or SO₂ group,
R², R³, R⁴, R⁵, R⁷, R⁸, R¹¹, R¹² are each independently alkyl, aryl or heteroaryl,
m, n, q, r, t, u, x, y are each independently 0, 1, 2 or 3
R⁶, R⁹, R¹⁰ are each independently alkyl, aryl, alkoxy or aryloxy,
s, v, w are each dependently 0, 1 or 2,
B is an alkylene bridge —CH₂—CₖH₂ₖ— in which one or more nonadjacent CH₂ groups of the —CₖH₂ₖ— unit may be replaced by oxygen or NR,
R is hydrogen or alkyl,
k is 0, 1, 2, 3, 4, 5, 6, 7 or 8,
j is 0 or 1 and
z is 1 or 2.

10. The method of using according to claim 9, wherein the variables of the formula I compound are defined as follows:
X is an SO or SO— group,
R¹ is hydrogen, methyl, ethyl, cyclohexyl, pyrrolidin-2-yl, pyrrolidin-3-yl, piperidin-2-yl, piperidin-3-yl, piperidin-4-yl, phenyl, 4-alkylphenyl, 4-alkoxyphenyl, 2,4,6-trialkylphenyl, 2,4,6-trialkoxyphenyl, furan-2-yl, furan-3-yl, pyrrol-2-yl, pyrrol-3-yl, thiophen-2-yl, thiophen-3-yl, pyridin-2-yl, pyridin-3-yl, pyridin-4-yl, pyrimidin-2-yl, pyrimidin-4-yl, pyrimidin-5-yl, sym-triazinyl, phenyl, 4-alkoxyphenyl,
a moiety of formula II 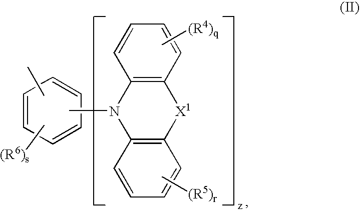
a moiety of formula III 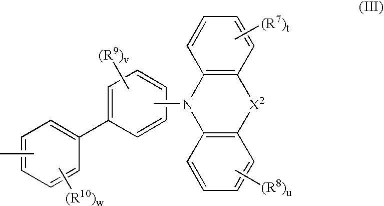
or
a moiety of formula IV 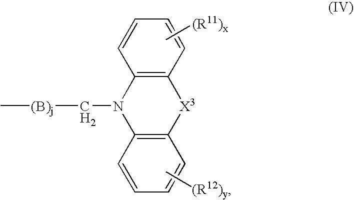
X¹, X², X³ are each independently, and independently of X, an SO or SO₂ group,
R², R³, R⁴, R⁵, R⁷, R⁸, R¹¹, R¹² are each independently aryl.
m, n, q, r, t, u, x, y are each independently 0 or 1,
R⁶, R⁹, R¹⁰ are each independently alkyl or alkoxy,
s, v, w are each independently 0 or 1,
B is an alkylene bridge —CH₂—CₖH₂ₖ—,
k is 0, 1, 2, 3, 4, 5, 6, 7 or 8,
j is 0 or 1 and
z is 1 or 2.

11. The method of using according to claim 9, wherein compounds of formula I are matrix materials in the light-emitting layer of organic light-emitting diodes.

12. The method of using according to claim 10, wherein compounds of formula I are matrix materials in the light-emitting layer of organic light-emitting diodes.

13. An organic light-emitting diode comprising a light-emitting layer, wherein the light-emitting layer comprises a least one compound of formula I according to claim 9 as a matrix material and at least one further substance distributed therein as an emitter.

14. An organic light-emitting diode comprising a light-emitting layer, wherein the light-emitting layer comprises at least one compound of formula I according to claim 10 as a matrix material and at least one further substance distributed therein as an emitter.

15. A light-emitting layer comprising at least one compound of formula I according to claim 9 as a matrix material and at least one further substance distributed therein as an emitter.

16. A light-emitting layer comprising at least one compound of formula I according to claim 10 as a matrix material and at least one further substance distributed therein as an emitter.

17. A light-emitting layer consisting of one or more compounds of formula I according to claim 9 as a matrix material and at least one further substance distributed therein an emitter.

18. A light-emitting layer consisting of one or more compounds of formula I according to claim 10 as a matrix material and at least one further substance distributed therein as an emitter.

19. An organic light-emitting diode comprising, the light-emitting layer according to claim 15.

20. An organic light-emitting diode comprising the light-emitting layer according to claim 16.

21. A device selected from the group consisting of stationary visual display units such as visual display units of computers, televisions, visual display units in printers, kitchen equipment aid advertising panels illuminations information panels and mobile visual display units such as visual display units in mobile telephones, laptops, digital cameras, vehicles and destination displays in buses and trains comprising the organic light-emitting diode according to claim 13.

22. A device selected from the group consisting of stationary visual display units such as visual display units of computers, televisions, visual display units in printers, kitchen equipment and advertising panels, illuminations information panels and mobile visual display units such as visual display units in mobile telephones, laptops, digital cameras, vehicles and destination displays in buses and trains, comprising the organic light-emitting diode according to claim 14.

23. A device selected from the group consisting of stationary visual display units such as visual display units of computers, televisions, visual display units in printers, kitchen equipment and advertising panels, illuminations, information panels and mobile visual display units such as visual display units in mobile telephones, laptops, digital cameras, vehicles and destination displays in buses and trains, comprising the organic light-emitting diode according to claim 19.

24. A device selected from the group consisting of stationary visual display units such as visual display units of computers, televisions, visual display units n printers, kitchen equipment and advertising panels, illuminations, information panels and mobile visual display units such as visual display u nits in mobile telephones, laptops, digital cameras, vehicles and destination displays in buses and trains, comprising the organic light-emitting diode according to claim 20.
